(19) United States
(12) Patent Application Publication
(10) Pub. No.: US 2025/0203844 A1
(43) Pub. Date: Jun. 19, 2025

(54) SEMICONDUCTOR DEVICE AND METHOD FOR FABRICATING THE SAME

(71) Applicant: SK hynix Inc., Gyeonggi-do (KR)

(72) Inventor: Seung Hwan KIM, Gyeonggi-do (KR)

(21) Appl. No.: 18/951,691

(22) Filed: Nov. 19, 2024

(30) Foreign Application Priority Data
Dec. 15, 2023 (KR) 10-2023-0183582

(51) Int. Cl. H10B 12/00

(52) U.S. Cl. CPC H10B 12/0335; H10B 12/315; H10B 12/485; H10B 12/488

(57) ABSTRACT

Disclosed are a semiconductor device including highly integrated memory cells, and a method for fabricating the semiconductor device. A method for fabricating a semiconductor device includes forming a mold stack of conductive layers over a lower structure, the mold stack including a first horizontal conductive line, a second horizontal conductive line, and a pad between the first horizontal conductive line and the second horizontal conductive line; forming a vertical stack of a stair structure whose height is gradually decreased in a stack direction that the conductive layers are stacked by selectively etching a portion of the mold stack; forming contact holes in the stair structure, wherein heights of the contact holes are gradually decreased in the stack direction; and forming contact plugs in the contact holes, the contact plugs coupled to the conductive layers, respectively.

### CROSS-REFERENCE TO RELATED APPLICATIONS

The present application claims priority under 35 U.S.C. 119(a) to Korean Patent Application No. 10-2023-0183582, filed on Dec. 15, 2023, which is incorporated herein by reference in its entirety.

### BACKGROUND

### 1. Field

Embodiments of the present disclosure relate to a semiconductor device, and more particularly, to a semiconductor device including three-dimensional (3D) memory cells, and a method for fabricating the semiconductor device.

### 2. Description of the Related Art

In order to cope with the demands for large capacity and miniaturization of memory devices, technology for providing a three-dimensional (3D) memory device in which a plurality of memory cells are stacked is recently disclosed.

### SUMMARY

Embodiments of the present disclosure are directed to a semiconductor device including highly integrated memory cells, and a method for fabricating the semiconductor device.

In accordance with an embodiment of the present disclosure, a method for fabricating a semiconductor device includes forming a mold stack of conductive layers over a lower structure, the mold stack including a first horizontal conductive line, a second horizontal conductive line, and a pad between the first horizontal conductive line and the second horizontal conductive line; forming a vertical stack of a stair structure whose height is gradually decreased in a stack direction that the conductive layers are stacked by selectively etching a portion of the mold stack; forming contact holes in the stair structure, wherein heights of the contact holes are gradually decreased in the stack direction; and forming contact plugs in the contact holes, the contact plugs coupled to the conductive layers, respectively.

In accordance with another embodiment of the present disclosure, a method for fabricating a semiconductor device includes forming a first stack of first conductive layers over a lower structure, each first conductive layer including a pair of an upper horizontal conductive line and a lower horizontal conductive line; forming a second stack of second conductive layers extending from the first stack over the lower structure, each second conductive layer including a first horizontal conductive line, a second horizontal conductive line, and a pad between the first horizontal conductive line and the second horizontal conductive line; forming a vertical stack of a stair structure by selectively etching a portion of the second stack, the vertical stack including a plurality of levels whose heights are gradually decreased in a stack direction that the second conductive layers are stacked; forming contact holes in the stair structure, wherein heights of the contact holes are gradually decreased in the stack direction; and forming contact plugs in the contact holes, the contact plugs coupled to the second conductive layers, respectively.

In accordance with another embodiment of the present disclosure, a semiconductor device includes a lower structure; a first region formed over the lower structure, the first region including a plurality of first conductive layers that are vertically stacked in a first direction; a second region including a plurality of second conductive layers stacked in the first direction and having different horizontal lengths, the second region extend from the first region; and a plurality of contact structures respectively coupled to the second conductive layers, wherein each of the second conductive layers includes: a first horizontal conductive line; a second horizontal conductive line; and a pad between the first horizontal conductive line and the second horizontal conductive line.

In accordance with another embodiment of the present disclosure, a method for fabricating a semiconductor device includes forming a mold stack of metal layers including a first horizontal metal line, a second horizontal metal line, and a metal pad material between the first horizontal metal line and the second horizontal metal line over a lower structure; forming a vertical stack of a stair structure including a plurality of levels whose heights are gradually decreased in a direction that the metal layers are stacked by selectively etching a portion of the mold stack; forming contact holes whose heights are gradually decreased in the direction that the metal layers are stacked in the stair structure; and forming contact plugs respectively coupled to the metal layers in the contact holes.

In accordance with another embodiment of the present disclosure, a method for fabricating a semiconductor device includes forming a mold stack in which tungsten layers and inter-cell dielectric layers are alternately stacked over a lower structure; forming a vertical stack of a stair structure including a plurality of levels whose heights are gradually decreased in a direction that the tungsten layers are stacked by selectively etching a portion of the mold stack; forming contact holes whose heights are gradually decreased in the direction that the tungsten layers are stacked in the stair structure; and forming contact plugs respectively coupled to the tungsten layers in the contact holes. The tungsten layers of the mold stack may include an upper tungsten layer, a lower tungsten layer, and a pad tungsten layer between the upper tungsten layer and the lower tungsten layer.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view illustrating the memory cell shown in FIG. 1A.

FIG. 1C is a plan view illustrating a switching element shown in FIG. 1A.

FIG. 2 is a schematic plan view illustrating a semiconductor device in accordance with an embodiment of the present disclosure.

FIG. 3A is a schematic perspective view illustrating a first vertical stack WLS1 shown in FIG. 2.

FIG. 3B is a schematic cross-sectional view taken along a line A-A′ shown in FIG. 2.

FIG. 3C is a schematic cross-sectional view taken along a line B-B′ shown in FIG. 2.

FIG. 3D is a schematic cross-sectional view taken along a line C-C′ shown in FIG. 2.

FIGS. 4 to 22 illustrate a method for fabricating a semiconductor device in accordance with an embodiment of the present disclosure.

FIGS. 23 to 31 illustrate a method for forming a pad portion in accordance with an embodiment of the present disclosure.

FIGS. 32 to 34 are schematic cross-sectional views illustrating a method for fabricating a semiconductor device in accordance with another embodiment of the present disclosure.

FIGS. 35 to 37 are perspective views illustrating a memory cell array in accordance with other embodiments of the present disclosure.

### DETAILED DESCRIPTION

Embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The following embodiment relates to a three-dimensional memory cell, in which memory cells are vertically stacked to increase memory cell density and reduce parasitic capacitance.

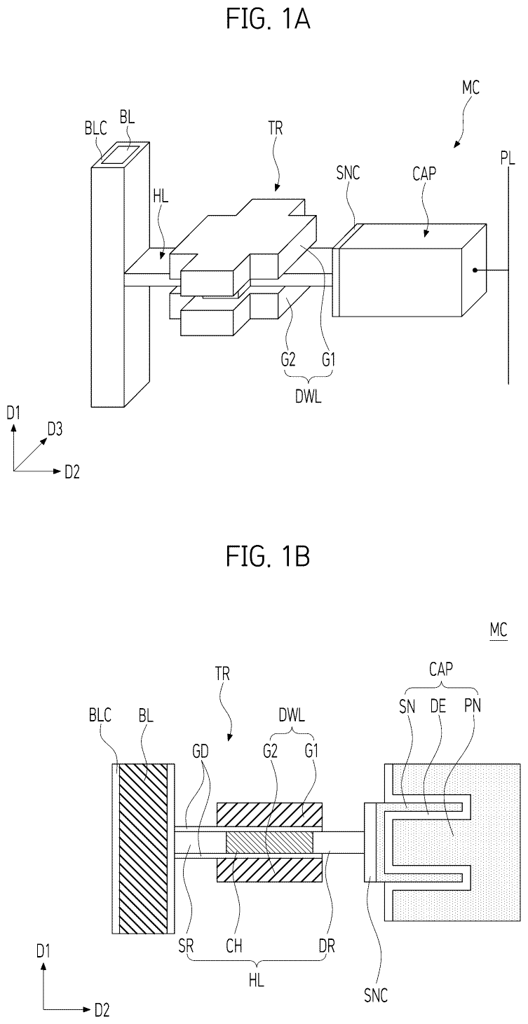

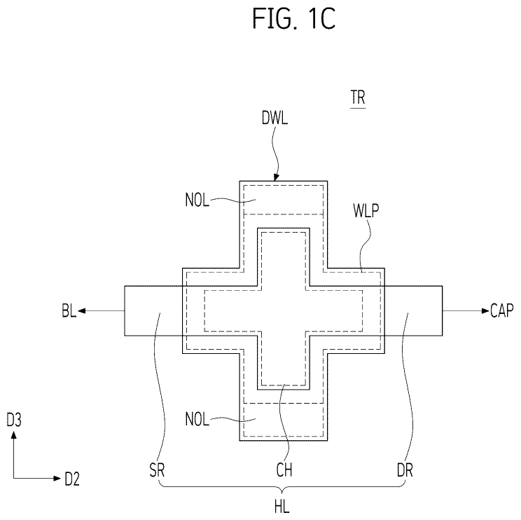

FIG. 1A is a schematic perspective view illustrating a memory cell MC in accordance with an embodiment of the present disclosure. FIG. 1B is a schematic cross-sectional view illustrating the memory cell shown in FIG. 1A. FIG. 1C is a plan view illustrating a switching element shown in FIG. 1A.

Referring to FIGS. 1A to 1C, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a stack of titanium nitride and tungsten (TiN/W).

The switching element TR may have a function of controlling the voltage (or current) supply to the data storage element CAP in a data write operation and a data read operation for the data storage element CAP. The switching element TR may include a horizontal layer HL, an inter-level dielectric layer GD, and a second conductive line DWL. The second conductive line DWL may include a horizontal conductive line or a horizontal word line, and the horizontal layer HL may include an active layer. The switching element TR may include a transistor. In this case, the second conductive line DWL may function as a gate electrode. The switching element TR may also be referred to as an access element or a selection element. The second conductive line DWL may be referred to as a horizontal gate electrode or a horizontal word line.

The horizontal layer HL may extend in a second direction D2 intersecting with the first direction D1. The second conductive line DWL may extend in a third direction D3 intersecting with the first direction D1 and the second direction D2. The first direction D1 may be a vertical direction, the second direction D2 may be a first horizontal direction, and the third direction D3 may be a second horizontal direction. The horizontal layer HL may extend in the first horizontal direction (i.e., the second direction D2), and the second conductive line DWL may extend in the second horizontal direction (i.e., the third direction D3).

The horizontal layer HL may be horizontally oriented in the second direction D2 from the first conductive line BL. The second conductive line DWL may have a double structure. For example, the second conductive line DWL may include an upper horizontal line G1 and a lower horizontal line G2 that are facing each other with the horizontal layer HL interposed therebetween. The inter-level dielectric layer GD may be formed on the upper surface and the lower surface of the horizontal layer HL. The upper horizontal line G1 may be disposed over the horizontal layer HL, and the lower horizontal line G2 may be disposed below the horizontal layer HL. The second conductive line DWL may include a pair of the upper horizontal line G1 and the lower horizontal line G2. In the second conductive line DWL, the same driving voltage may be applied to the upper horizontal line G1 and the lower horizontal line G2. For example, the upper horizontal line G1 and the lower horizontal line G2 may form a pair to be coupled to a single memory cell MC. According to another embodiment of the present disclosure, different driving voltages may be applied to the upper horizontal line G1 and the lower horizontal line G2. In this case, one horizontal line among the upper horizontal line G1 and the lower horizontal line G2 may serve as a back gate or a shield gate.

Referring back to FIG. 1C, each of the upper horizontal line G1 and the lower horizontal line G2 may have a width in the second direction D2, for example, a width of an overlapping portion that overlaps with the horizontal layer HL, to be greater than a width of a non-overlapping portion that does not overlap with the horizontal layer HL. Due to this width difference, the second conductive line DWL may have a notch-shaped sidewall. The second conductive line DWL may include a channel overlapping portion WLP and a channel non-overlapping portion NOL. The channel overlapping portion WLP may refer to a portion that overlaps with the channel CH of the horizontal layer HL. The channel non-overlapping portion NOL may refer to a portion that does not overlap with the horizontal layer HL. The channel overlapping portion WLP may have a cross shape or a rhombus shape.

From the perspective of a top view, the horizontal layer HL may have a cross shape or a rhombus shape. According to another embodiment of the present disclosure, the side surfaces of the horizontal layer HL may have a bent shape or a rounded shape.

The horizontal layer HL may include a semiconductor material. For example, the horizontal layer HL may include polysilicon, monocrystalline silicon, germanium, or silicon-germanium. According to another embodiment of the present disclosure, the horizontal layer HL may include an oxide semiconductor material. For example, the oxide semiconductor material may include Indium Gallium Zinc Oxide (IGZO). According to another embodiment of the present disclosure, the horizontal layer HL may include a conductive metal oxide. According to another embodiment of the present disclosure, the horizontal layer HL may include two-dimensional material. For example, the two-dimensional material may include MoS₂, MoSe₂, MoTe₂, WS₂, WSe₂, or WTe₂.

The upper surface and the lower surface of the horizontal layer HL may have a flat surface. The upper surface and the lower surface of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or a thin-body. The channel CH and the channel overlapping portion WLP of the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

The first doped region SR and the second doped region DR may be doped with impurities of the same conductive type. The first doped region SR and the second doped region DR may be doped with an N-type conductive impurity or a P-type conductive impurity. The first doped region SR and the second doped region DR may include at least one impurity selected from the group including arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions, respectively. The inter-level dielectric layer GD may be disposed between the horizontal layer HL and the second conductive line DWL. The inter-level dielectric layer GD may also be referred to as a gate dielectric layer. The inter-level dielectric layer GD may also be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by a thermal oxidation process of a semiconductor material.

The second conductive line DWL may include a metal-based material, a semiconductor material, or a combination thereof. The second conductive line DWL may include titanium nitride, tungsten, polysilicon, or a combination thereof. For example, the second conductive line DWL may include a titanium nitride and tungsten (TiN/W) stack in which titanium nitride and tungsten are sequentially stacked. The second conductive line DWL may include an N-type work function material or a P-type work function material. The N-type work function material may have a low work function of approximately 4.5 eV or less. The P-type work function material may have a high work function of approximately 4.5 eV or greater. The second conductive line DWL may include a stack of a low work function material and a high work function material.

The data storage element CAP may include a memory element, such as a capacitor. The data storage element CAP may be disposed horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be disposed horizontally in the second direction D2. The first electrode SN may include an inner space and a plurality of outer surfaces. The inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1. The horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

The data storage element CAP may have a three-dimensional structure. The first electrode SN may have a three-dimensional structure, which may be a horizontal three-dimensional structure which is oriented in the second direction D2. In an embodiment of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. The dielectric layer DE and the second electrode PN may be disposed on the cylindrical inner surfaces of the first electrode SN.

According to another embodiment of the present disclosure, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the first electrode SN, titanium nitride (TiN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the aforementioned high-k materials.

The dielectric layer DE may be formed of a zirconium-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as zirconium oxide (ZrO₂)-based layers. According to another embodiment of the present disclosure, the dielectric layer DE may be formed of hafnium (Hf)-based oxide. The dielectric layer DE may be a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide (HfO₂)-based layers. In the ZA stack, the ZAZ stack, the HA stack, and the HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Therefore, the dielectric layer DE may include a stack of a high-k material and a high band gap material having a greater band gap energy than the high-k material. In addition to aluminum oxide (Al₂O₃), the dielectric layer DE may include silicon oxide (SiO₂) as another high band gap material. By including the high band gap material, the dielectric layer DE may be able to suppress the leakage current. The high band gap material may be thinner than the high-k material. According to another embodiment of the present disclosure, the dielectric layer DE may include a stack structure in which high-k materials and high band gap materials are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack. In the above stack structure, the aluminum oxide (Al₂O₃) may be thinner than the zirconium oxide (ZrO₂) and the hafnium oxide (HfO₂).

According to another embodiment of the present disclosure, the dielectric layer DE may include a high-k material and a high band gap material. The dielectric layer DE may have a laminated structure in which a plurality of high-k materials and a plurality of high band gap materials are stacked, or a mixed structure in which the high-k material and the high band gap material are intermixed.

According to another embodiment of the present disclosure, the dielectric layer DE may include a ferroelectric material, an anti-ferroelectric material, or a combination thereof. For example, the dielectric layer DE may include HfZrO.

According to another embodiment of the present disclosure, the dielectric layer DE may include a combination of a high-k material and a ferroelectric material, a combination of a high-k material and an anti-ferroelectric material, a high-k material, or a combination of a ferroelectric material and an anti-ferroelectric material. According to another embodiment of the present disclosure, the dielectric layer DE may include a perovskite dielectric material. The perovskite dielectric material may include SrTiO₃, (Ba,Sr)TiO₃, BaTiO₃, PbTiO₃, PZT, PLZT, or PbTiO₃.

According to another embodiment of the present disclosure, an interface control layer for improving leakage current may be further formed between the first electrode SN and the dielectric layer DE. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

For example, the memory cell MC may include a thyristor, the first conductive line BL may be a cathode line, and the data storage element CAP may be replaced with an anode line. The horizontal layer HL may include four semiconductor layers that are stacked in the second direction D2. The thyristor may include a first diode and a second diode that are coupled in series. When a forward bias of the same voltage is applied to the thyristor, the thyristor may have a high conductance state in which a large amount of current flows or a low conductance state in which a small amount of current flows or no current flows. The memory cell MC in accordance with the embodiment of the present disclosure may have a ‘1’ state and a ‘0’ state according to the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and the first doped region SR and the second doped region DR may include the impurities diffused from the first contact node BLC and the second contact node SNC, respectively.

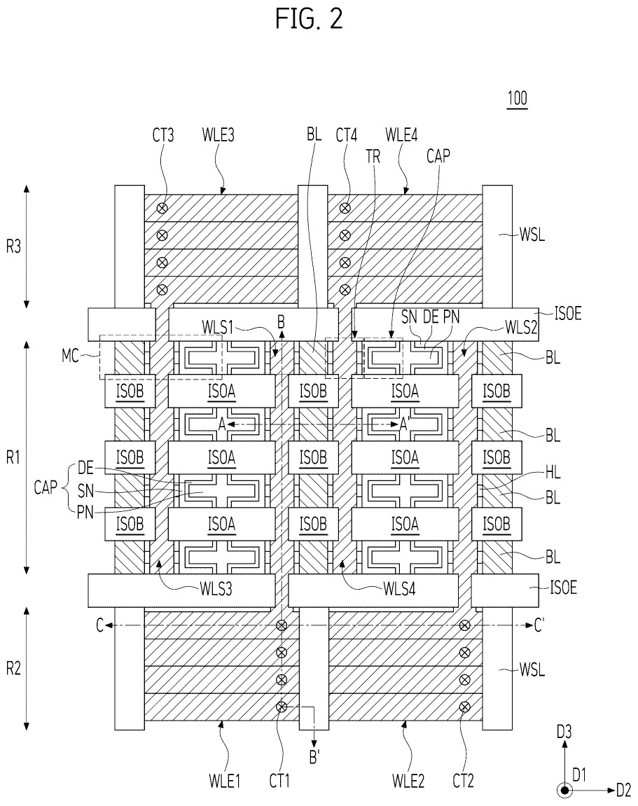

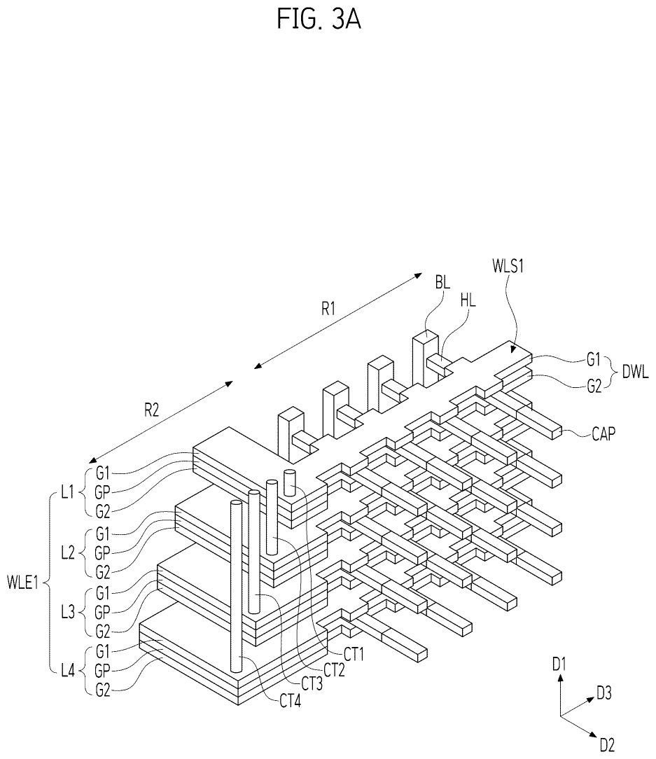

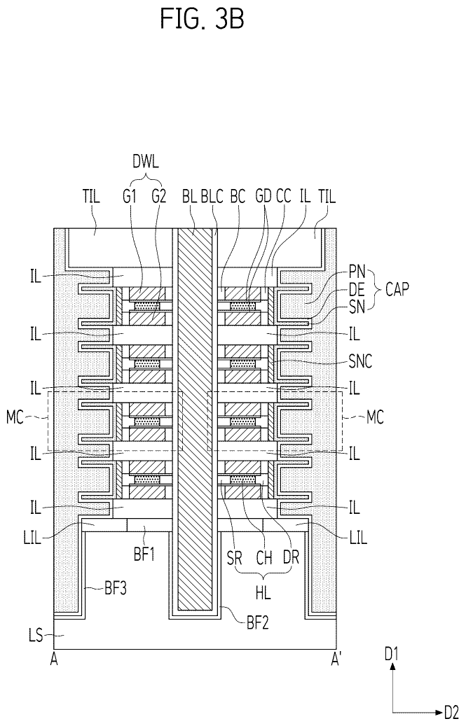

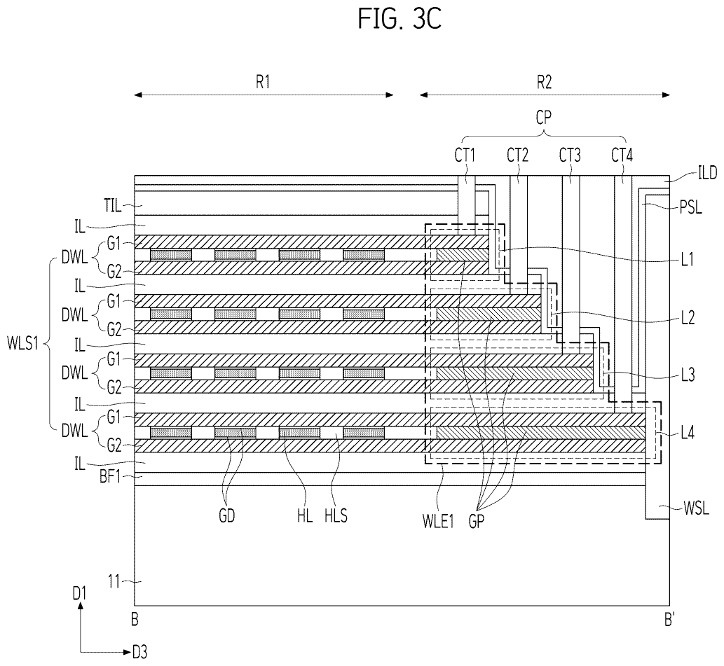

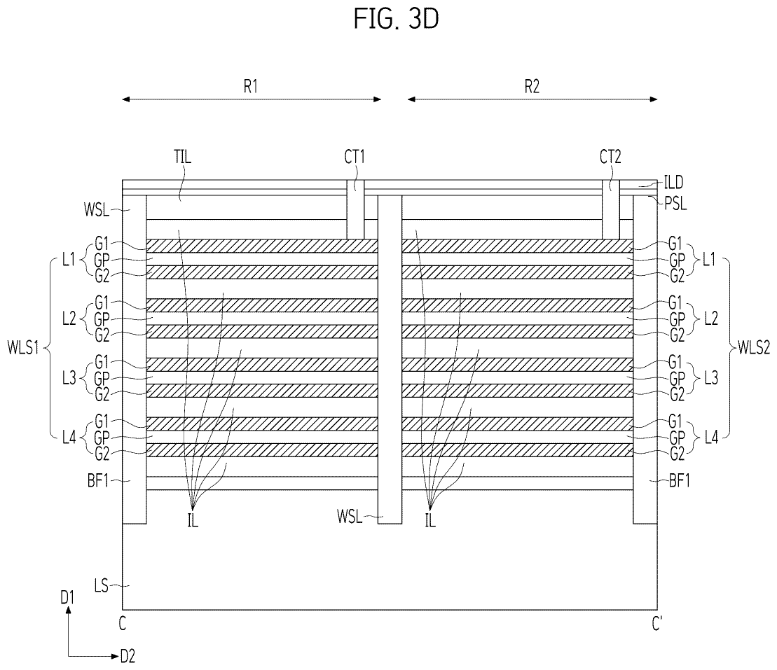

FIG. 2 is a schematic plan view illustrating a semiconductor device 100 in accordance with an embodiment of the present disclosure. FIG. 3A is a schematic perspective view illustrating a first vertical stack WLS1 shown in FIG. 2. FIG. 3B is a schematic cross-sectional view taken along a line A-A′ shown in FIG. 2. FIG. 3C is a schematic cross-sectional view taken along a line B-B′ shown in FIG. 2. FIG. 3D is a schematic cross-sectional view taken along a line C-C′ shown in FIG. 2.

Referring to FIGS. 2, 3A, 3B, 3C, and 3D, the semiconductor device 100 may include a first region R1 and a second region R2. The first region R1 may be a region where memory cells MC are formed, and the second region R2 may be a region where contact structures CT1 to CT4 are formed. The contact structures CT1 to CT4 of the second region R2 may be coupled to portions of the memory cells MC. The semiconductor device 100 may further include a third region R3. The third region R3 may be a region where contact structures CT1 to CT4 are formed, just like the second region R2. The first region R1 may be referred to as a memory cell array region, and the second and third regions R2 and R3 may be referred to as connection regions.

The semiconductor device 100 may include a three-dimensional array of memory cells MC. Each of the memory cells MC will be described with reference to FIGS. 1A to 1C. Each of the memory cells MC may include a first conductive line BL, a switching element TR, and a data storage element CAP. The switching element TR may include a horizontal layer HL, an inter-level dielectric layer GD, and a second conductive line DWL. The data storage element CAP may include a first electrode SN, a dielectric layer DE, and a second electrode PN. The three-dimensional array of the memory cells MC may be formed in the first region R1.

The three-dimensional array of the memory cells MC may include a column array of memory cells MC and a row array of memory cells MC. The column array of the memory cells MC may include a plurality of memory cells MC that are stacked in the first direction D1. The row array of the memory cells MC may include a first row array in which a plurality of memory cells MC are horizontally disposed in the second direction D2, and a second row array in which a plurality of memory cells MC are horizontally disposed in the third direction D3. In the column array, the memory cells MC stacked in the first direction D1 may share one first conductive line BL. In the column array, the memory cells MC stacked in the first direction D1 may share a common plate PL. The first row array of the row array may have two memory cells MC disposed horizontally in the second direction D2 to share one first conductive line BL. The first row array of the row array may have two memory cells MC disposed horizontally in the second direction D2 to share the common plate PL. The second row array of the row array may have memory cells MC disposed horizontally in the third direction D3 to share one second conductive line DWL. The structure that shares the first conductive line BL or the structure that shares the common plate PL may be referred to as a mirror-type structure.

The three-dimensional array of the memory cells MC may be referred to as a memory cell array. Therefore, the semiconductor device 100 may include a plurality of memory cell arrays. The memory cell arrays may include a column memory cell array and a row memory cell array.

The semiconductor device 100 may include a plurality of vertical stacks WLS1, WLS2, WLS3 and WLS4 that extend long in the third direction D3. The vertical stacks WLS1 to WLS4 may be disposed in the first region R1. Each of the vertical stacks WLS1 to WLS4 may be a portion of a sub-memory cell array. Each of the sub-memory cell arrays may include a column array of memory cells MC and a row array of memory cells MC.

The vertical stacks WLS1 to WLS4 may refer to a stack of a plurality of second conductive lines DWL that are stacked in the first direction D1. The second conductive lines DWL of the vertical stacks WLS1 to WLS2 may have an integrated structure that extends from the first region R1 to the second region R2. The second conductive lines DWL of the vertical stacks WLS3 to WLS4 may have an integrated structure that extends from the first region R1 to the third region R3.

The vertical stacks WLS1 to WLS4 may include pad portions WLE1 to WLE4. The pad portions WLE1 and WLE2 of the vertical stacks WLS1 to WLS2 may be disposed in the second region R2. The pad portions WLE3 and WLE4 of the vertical stacks WLS3 to WLS4 may be disposed in the third region R3. The pad portions WLE1 to WLE4 may have a stair structure including a stack of the second conductive lines DWL. The contact structures CT1 to CT4 may be coupled to the pad portions WLE1 to WLE4, respectively.

Inter-cell dielectric layers IL may be disposed between the memory cells MC that are stacked in the first direction D1. The inter-cell dielectric layers IL may include silicon oxide. The inter-cell dielectric layers IL may be referred to as horizontal inter-cell dielectric layers. A top dielectric layer TIL may be disposed over the uppermost-level inter-cell dielectric layer IL.

Cell dielectric layers ISOA and ISOB may be disposed between the memory cells MC that are disposed adjacent to each other in the third direction D3. The cell dielectric layers ISOA and ISOB may be referred to as vertical inter-cell dielectric layers. The cell dielectric layers ISOA and ISOB may include silicon oxide, silicon carbon oxide (SiCO), silicon nitride, or a combination thereof. The cell dielectric layers ISOA and ISOB may include first cell dielectric layers ISOA and second cell dielectric layers ISOB. The first cell dielectric layers ISOA and the second cell dielectric layers ISOB may extend vertically in the first direction D1. The first cell dielectric layers ISOA and the second cell dielectric layers ISOB may have a pillar structure extending vertically in the first direction D1. The first cell dielectric layers ISOA and the second cell dielectric layers ISOB may be alternately and repeatedly disposed in the second direction D2. The first cell dielectric layers ISOA may be disposed between the data storage elements CAP in the third direction D3. The second cell dielectric layers ISOB may be disposed between the first conductive lines BL in the third direction D3. The second conductive lines DWL may be disposed between the first cell dielectric layers ISOA and the second cell dielectric layers ISOB in the second direction D2. Each of the first cell dielectric layers ISOA and the second cell dielectric layers ISOB may include a stack of a cell isolation liner layer and a cell isolation gap-fill layer. The cell isolation liner layers may include silicon oxide, and the cell isolation gap-fill layers may include silicon carbon oxide.

Edge cell dielectric layers ISOE may be disposed between the first region R1 and the second region R2. The edge cell dielectric layers ISOE may be disposed between the first region R1 and the third region R3. The edge cell dielectric layers ISO3 may be disposed alternately in the second direction D2.

The three-dimensional array of the memory cells MC may be disposed over the lower structure LS. The three-dimensional array of the memory cells MC may include a plurality of second conductive lines DWL that are vertically stacked in the first direction D1. The three-dimensional array of the memory cells MC may include a plurality of horizontal layers HL that are vertically stacked in the first direction D1. The three-dimensional array of the memory cells MC may include a plurality of data storage elements CAP that are vertically stacked in the first direction D1. The three-dimensional array of the memory cells MC may include a plurality of first conductive lines BL that are spaced apart in the third direction D3.

Each of the second conductive lines DWL may include a channel overlapping portion WLP and channel non-overlapping portions NOL as illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notch-shaped sidewall.

A plurality of first passivation layers BF1 may be disposed between the lowermost-level second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2 and BF3 may include a dielectric material. The first to third passivation layers BF1, BF2 and BF3 may include silicon oxide. The first conductive line BL, the second conductive lines DWL and the data storage elements CAP may be electrically disconnected from the lower structure LS by the first to third passivation layers BF1, BF2 and BF3. The first to third passivation layers BF1, BF2 and BF3 may be referred to as bottom dielectric layers or bottom passivation layers. A lowermost-level inter-cell dielectric layer LIL may be disposed between the first passivation layers BF1 and the data storage elements CAP.

The first conductive lines BL may extend vertically in the first direction D1 over the lower structure LS. The horizontal layers HL may extend in the second direction D2 intersecting with the first direction D1. The second conductive lines DWL may extend in the third direction D3 intersecting with the first direction D1 and the second direction D2.

From the perspective of a top view, the horizontal layers HL may have a cross shape or a rhombus shape. According to another embodiment of the present disclosure, the side surfaces of the horizontal layers HL may have a bent shape or a rounded shape. As illustrated in FIG. 1B, the horizontal layers HL may include a channel CH, a first doped region SR between the channel CH and the first conductive line BL, and a second doped region DR between the channel CH and the data storage element CAP.

A first capping layer BC may be disposed between the first conductive line BL and the second conductive line DWL. A second capping layer CC may be disposed between the second conductive line DWL and the first electrode SN of the data storage element CAP. The first capping layer BC may be disposed between the upper horizontal line G1 and the first conductive line BL. Also, the first capping layer BC may be disposed between the lower horizontal line G2 and the first conductive line BL. The second capping layer CC may be disposed between the upper horizontal line G1 and the first electrode SN of the data storage element CAP. Also, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride.

The memory cell MC may further include a first contact node BLC and a second contact node SNC. The first contact node BLC may surround an outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon. The first doped region SR and the second doped region DR may include the impurities diffused from the first contact node BLC and the second contact node SNC, respectively.

The horizontal layers HL of the switching elements TR disposed horizontally in the third direction D3 may share one second conductive line DWL. The horizontal layers HL of the switching elements TR horizontally disposed in the third direction D3 may be coupled to different first conductive lines BL. The switching elements TR stacked in the first direction D1 may share one first conductive line BL. Each of the switching elements TR stacked in the first direction D1 may include a second conductive line DWL.

The first cell dielectric layers ISOA may be disposed between the first electrodes SN of the data storage elements CAP in the third direction D3. The first electrodes SN may be isolated from each other by the first cell dielectric layers ISOA. The second electrodes PN of the data storage elements CAP may be coupled to a common plate PL.

The lower structure LS may include a semiconductor substrate, a metal interconnection structure, an insulating structure, a conductive structure, a bonding pad structure, another memory or a peripheral circuit portion. For example, the lower structure LS may include a structure in which the peripheral circuit portion, the metal interconnection structure, and the bonding pad structure are sequentially stacked. The peripheral circuit portion may include one or more control circuits for driving the three-dimensional array of the memory cells MC. The one or more control circuits of the peripheral circuit portion may include an N-channel transistor, a P-channel transistor, a CMOS circuit, or a combination thereof. The one or more control circuits of the peripheral circuit portion may include an address decoder circuit, a read circuit, a write circuit, and the like. The one or more control circuits of the peripheral circuit portion may include a planar channel transistor, a recess channel transistor, a buried gate transistor, a fin channel transistor (FinFET), and the like. For example, the peripheral circuit portion may include sub-word line drivers and a sense amplifier. The first conductive lines BL may be coupled to the sense amplifier, and the second conductive lines DWL may be coupled to the sub-word line drivers.

According to another embodiment of the present disclosure, the semiconductor device 100 may include a first substrate where the three-dimensional array of the memory cells MC is formed, a second substrate where the peripheral circuit portion is formed, and the bonding pad structure for bonding the three-dimensional array of the memory cells MC with the peripheral circuit portion.

According to another embodiment of the present disclosure, the semiconductor device 100 may have a Cell-over-PERI (COP) structure or a PERI-over-Cell (POC) structure. In the COP structure, the peripheral circuit portion may be disposed at a lower level than the three-dimensional array of the memory cells MC. In the POC structure, the three-dimensional array of the memory cells MC may be disposed at a lower level than the peripheral circuit portion. When the lower structure LS includes the peripheral circuit portion in FIG. 3C, the semiconductor device 100 may include the COP structure.

Each of the COP structure and the POC structure may include a bonding pad structure. The COP structure including the bonding pad structure may flip the substrate where the three-dimensional array of the memory cells MC is formed, and bond the peripheral circuit portion with a wafer by using the bonding pad structure. The POC structure including the bonding pad structure may flip the substrate where the peripheral circuit portion is formed, and bond the three-dimensional array of the memory cells MC with a wafer by using the bonding pad structure.

According to another embodiment of the present disclosure, the array of the memory cells MC may include a Dynamic Random Access Memory (DRAM), an embedded DRAM, a NAND, a ferroelectric Random Access Memory (FeRAM), a Spin Transfer Torque Random Access Memory (STT-RAM), a Phase-Change Random Access Memory (PCRAM), or a Resistive Random Access Memory (ReRAM).

Referring back to FIG. 2, the vertical stacks may include first to fourth vertical stacks WLS1 to WLS4, and the pad portions may include first to fourth pad portions WLE1 to WLE4. The first to fourth pad portions WLE1 to WLE4 may be isolated from each other by a plurality of isolation slits WSL. The first to fourth pad portions WLE1 to WLE4 may be disposed in a zig-zag manner in the order of the first pad portion WLE1, the third pad portion WLE3, the second pad portion WLE2, and the fourth pad portion WLE4.

Referring again to FIG. 3A, the first vertical stack WLS1 and the first pad portion WLE1 may have an integrated structure. The first vertical stack WLS1 may be disposed in the first region R1 and the first pad portion WLE1 may be disposed in the second region R2. Each of the first vertical stack WLS1 and the first pad portion WLE1 may include second conductive lines DWL that are stacked in the first direction D1. The second conductive lines DWL may include a plurality of levels L1, L2, L3 and L4. For example, the first level L1 may refer to the uppermost-level second conductive line DWL, and the fourth level L4 may refer to the lowermost-level second conductive line DWL. The second level L2 may be lower than the first level L1, and the third level L3 may be lower than the second level L2. The fourth level L4 may be lower than the third level L3.

The fourth level L4, the third level L3, the second level L2, and the first level L1 may be sequentially stacked in the first direction D1.

In the first vertical stack WLS1 and the first pad portion WLE1, each of the second conductive lines DWL of the levels L1 to L4 may include a pair of an upper horizontal lines G1 and a lower horizontal lines G2.

As described above, the second conductive lines DWL may be disposed in the first region R1, and portions of the second conductive lines DWL may extend to the second region R2. The portions of the second conductive lines DWL disposed in the second region R2 may form a first pad portion WLE1. The first pad portion WLE1 may be referred to as a contact portion, an edge portion, or a connection portion.

In the first pad portion WLE1, each of the levels L1 to L4 may further include pads GP. The pads GP may be disposed between the upper horizontal line G1 and the lower horizontal line G2. Each pad GP may be electrically connected to the upper horizontal line G1 and the lower horizontal line G2. The first pad portion WLE1 may further include inter-cell dielectric layers IL that are disposed between the levels L1 to L4.

The second to fourth vertical stacks WLS2, WLS3 and WLS4 may also have the same structure as the structure of the first vertical stack WLS1. The second to fourth pad portions WLE2, WLE3 and WLE4 may also have the same structure as the structure of the first pad portion WLE1.

Each of the first to fourth vertical stacks WLS1 to WLS4 may further include horizontal layers HL and inter-level dielectric layers GD. The horizontal layers HL and the inter-level dielectric layers GD may be disposed between the upper horizontal line G1 and the lower horizontal line G2. The first to fourth vertical stacks WLS1 to WLS4 may further include inter-cell dielectric layers IL between the second conductive lines DWL. The inter-cell dielectric layers IL may extend from the first to fourth vertical stacks WLS1 to WLS4 to the first to fourth pad portions WLE1 to WLE4. The first to fourth pad portions WLE1 to WLE4 may not include the horizontal layers HL and the inter-level dielectric layers GD.

The lateral lengths of the pads GP in the third direction D3 may be different from each other. The pads GP disposed in the second region R2 and the horizontal layers HL disposed in the first region R1 may be spaced apart from each other. The pads GP may not be disposed in the first region R1.

The pads GP, the upper horizontal lines G1 and the lower horizontal lines G2 may include the same material. The pads GP, the upper horizontal lines G1 and the lower horizontal lines G2 may include a metal-based material. For example, the pads GP, the upper horizontal lines G1 and the lower horizontal lines G2 may include titanium nitride, tungsten or a combination thereof. The pads GP, the upper horizontal lines G1 and the lower horizontal lines G2 may include a metal-based material.

The second region R2 may include contact structures CT1 to CT4 respectively coupled to the second conductive lines DWL of the pad portions WLE11 to WLE4. The contact structures CT1 to CT4 may include contact plugs.

The second region R2 may include an alternating stack of the second conductive lines DWL and the inter-cell dielectric layers IL, and an array of the contact structures CT1 to CT4 disposed in the alternating stack, laterally spaced apart from each other in the horizontal direction (i.e., the third direction D3), and having different heights. The top surfaces of the contact structures CT1 to CT4 may be disposed on the same horizontal plane, and the bottom portions of the contact structures CT1 to CT4 may adjoin the second conductive lines DWL, respectively.

As described above, the second conductive lines DWL of the pad portions WLE1 to WLE4 may have a stair structure.

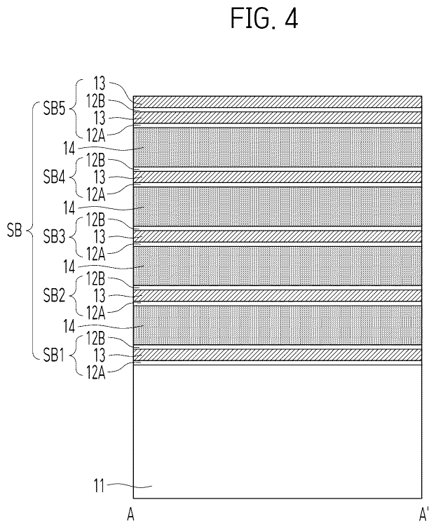

FIGS. 4 to 22 illustrate a method for fabricating a semiconductor device in accordance with an embodiment of the present disclosure. FIGS. 4 to 22 illustrate a method for fabricating a semiconductor device according to the line A-A′ shown in FIG. 2. Hereinafter, as for the first direction D1, the second direction D2, and the third direction D3, the first to third directions D1, D2 and D3 as illustrated in FIG. 2 may be referred to, respectively.

Referring to FIG. 4, a stack body SB may be formed over a lower structure 11. The lower structure 11 may be a material appropriate for semiconductor processing. The lower structure 11 may include one or more of a conductive material, a dielectric material, and a semiconductor material. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure 11 may also include another semiconductor material, such as germanium. The lower structure 11 may also include a III-V group semiconductor substrate, such as a compound semiconductor substrate, such as gallium arsenide (GaAs). The lower structure 11 may also include a Silicon-On-Insulator (SOI) substrate.

The stack body SB may include a plurality of sub-stacks that are alternately stacked. Each of the sub-stacks may include a first layer 12A, a second layer 13, a third layer 12B, and a fourth layer 14 that are sequentially stacked. The first layers 12A and the third layers 12B may be formed of the same material and may include silicon germanium or monocrystalline silicon germanium. The second layers 13 and the fourth layers 14 may be formed of the same material and may include monocrystalline silicon. The first layers 12A, the second layers 13, the third layers 12B, and the fourth layers 14 may be formed by an epitaxial growth process. The lowermost-level first layer 12A may serve as a seed layer during the epitaxial growth process. Each of the first layers 12A may be thinner than each of the second layers 13, and each of the fourth layers 14 may be thicker than each of the second layers 13.

According to the embodiment of the present disclosure, the stack body SB may include a plurality of fourth layers 14, a first sacrificial layer stack SB1, a second sacrificial layer stack SB2, a third sacrificial layer stack SB3, a fourth sacrificial layer stack SB4, and a fifth sacrificial layer stack SB5. The stack body SB may include the first stack SB1, the fourth layer 14, the second stack SB2, the fourth layer 14, the third stack SB3, the fourth layer 14, the fourth stack SB4, the fourth layer 14, and the fifth stack SB5 that are sequentially stacked. The second layer 13 may be disposed at the uppermost level of the stack body SB. Each of the first to fifth stacks SB1 to SB5 may be a three-layer stack of the first layer 12A, the second layer 13, and the third layer 12B. For example, when the first layers 12A and the third layers 12B include a silicon germanium layer, and the second layers 13 include a monocrystalline silicon layer, the first to fifth stacks SB1 to SB5 may include a stack of a first silicon germanium, a monocrystalline silicon, and a second silicon germanium (SiGe/Si/SiGe). The fifth stack SB5 may further include a second layer 13 over the three-layer stack of the first layer 12A, the second layer 13, and the third layer 12B.

The second layers 13 may include a first monocrystalline silicon layer, and the fourth layers 14 may include a second monocrystalline silicon layer. The second monocrystalline silicon layers may be thicker than the first monocrystalline silicon layers. Accordingly, the stack body SB may have a first stack SB1 disposed below the second monocrystalline silicon layers, and a second stack SB2 disposed over the second monocrystalline silicon layer. Each of the first and second stacks SB1 and SB2 may include a stack of a first silicon germanium layer, a first monocrystalline silicon layer, and a second silicon germanium layer. The second monocrystalline silicon layers may be thicker than the first monocrystalline silicon layers.

The first layers 12A, the second layers 13, and the third layers 12B may be referred to as ‘sacrificial layers’, and the fourth layers 14 may be referred to as recess target layers. The stack body SB may be referred to as a vertical stack. The stack body SB may be formed by alternating a plurality of sacrificial layers and the recess target layers. The sacrificial layers may include first to fifth stacks SB1 to SB5. Each of the first to fifth stacks SB1 to SB5 may include a three-layer stack of the first layer 12A, the second layer 13, and the third layer 12B. The recess target layers may include the fourth layers 14. Each of the sacrificial layers may include a three-layer stack of a first silicon germanium layer, a first monocrystalline silicon layer, and a second silicon germanium layer. Each of the recess target layers may include a single layer of a second monocrystalline silicon layer. Each of the second monocrystalline silicon layers may be thicker than each of the first monocrystalline silicon layers.

Referring back to FIGS. 2 to 3D described above, when memory cells are stacked, the first sacrificial layer stack SB1, the fourth layer 14, the second sacrificial layer stack SB2, the fourth layer 14, the third sacrificial layer stack SB3, the fourth layer 14, the fourth sacrificial layer stack SB4, the fourth layer 14, and the fifth sacrificial layer stack SB5 may be alternately stacked several times.

According to another embodiment of the present disclosure, the fourth layer 14 may include amorphous silicon or polysilicon.

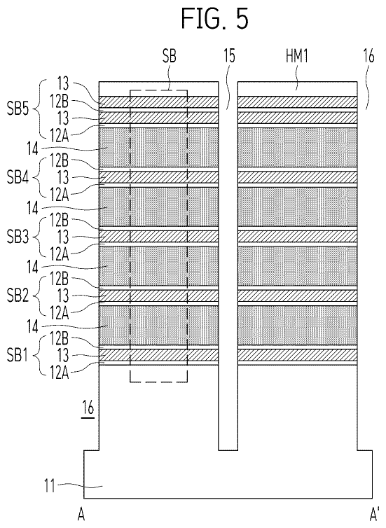

Referring to FIG. 5, portions of the stack body SB may be etched. As a result, a plurality of vertical openings 15 and 16 may be formed in the stack body SB. The vertical openings may include first vertical openings 15 and second vertical openings 16. From the perspective of a top view, the first vertical openings 15 and the second vertical openings 16 may be hole-shaped vertical openings. According to another embodiment of the present disclosure, the first vertical openings 15 and the second vertical openings 16 may be line-shaped vertical openings. From the perspective of a top view, the cross sections of the first and second vertical openings 15 and 16 may be square, circular, or oval.

As described above, a hard mask layer pattern HM1 may be formed to form vertical openings 15 and 16. The hard mask layer pattern HM1 may be formed by a double patterning process. The hard mask layer pattern HM1 may include silicon nitride. The hard mask layer pattern HM1 may be formed by an etching process using a mask layer. The hard mask layer pattern HM1 may have a plurality of hole-shaped openings defined therein.

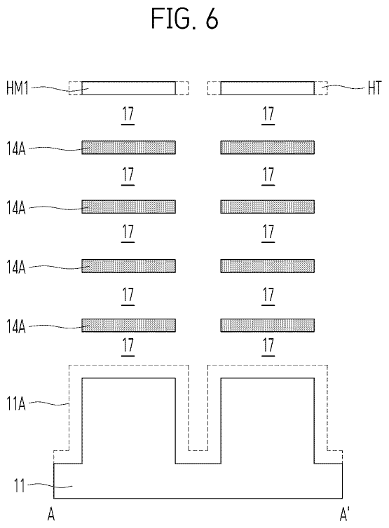

Referring to FIG. 6, a portion HT of the hard mask layer pattern HM1 may be trimmed.

The first and third layers 12A and 12B may be selectively removed through the first and second vertical openings 15 and 16. The first layers 12A and the third layers 12B may be selectively removed based on the difference between the etching selectivities of the second and fourth layers 13 and 14 and the etching selectivities of the first and third layers 12A and 12B. The first layers 12A and the third layers 12B may be removed by a wet etching process or a dry etching process. For example, when the first layers 12A and the third layers 12B include a silicon germanium layer and the second layers 13 and the fourth layers 14 include a monocrystalline silicon layer, the silicon germanium layers may be etched by using an etchant or etching gas having a selectivity with respect to the monocrystalline silicon layers.

The second layers 13 and the fourth layers 14 may be recessed. The second layers 13 and the fourth layers 14 may be recessed by a wet etching process or a dry etching process. According to the embodiment of the present disclosure, the fourth layers 14 may be partially etched while the second layers 13 are removed. As a result, the second layers 13 may be removed, and the fourth layers 14 may become thin as indicated by a reference numeral ‘14A’. The recess process for forming the thin fourth layer 14, which is the preliminary horizontal layers 14A, may be referred to as a thinning process or a trimming process of the fourth layers 14. The preliminary horizontal layers 14A may be formed by recessing the upper surfaces, lower surfaces, and side surfaces of the fourth layers 14. The preliminary horizontal layers 14A may be referred to as a thin-body active layer. The preliminary horizontal layers 14A may include a monocrystalline silicon layer. The recess process for forming the preliminary horizontal layers 14A may use, for example, Hot SC-1 (HSC1). HSC1 may include a solution in which ammonium hydroxide (NH₄OH), hydrogen peroxide (H₂O₂), and water (H₂O) are mixed in a ratio of approximately 1:4:20. The second layers 13 and the fourth layers 14 may be selectively etched by using the HSC1.

The preliminary horizontal layers 14A may be formed by the recess process that is performed for the fourth layers 14 as described above. Horizontal recesses 17 may be formed between the preliminary horizontal layers 14A. Each of the upper surface and the lower surface of the preliminary horizontal layers 14A may include a flat surface.

From the perspective of a top view, the preliminary horizontal layers 14A may have a cross shape. The side surfaces of the preliminary horizontal layers 14A may have a bent shape or a rounded shape.

After the preliminary horizontal layers 14A are formed, the first and second vertical openings 15 and 16 of FIG. 5 may be expanded. The preliminary horizontal layers 14A may be spaced apart from each other by the first and second vertical openings 15 and 16 in the second direction D2. The preliminary horizontal layers 14A may have a shape in which a plurality of cross shapes are merged in the third direction D3.

While the preliminary horizontal layers 14A are formed, the surface of the lower structure 11 may be recessed to a predetermined depth (see a reference numeral ‘11A’). As a result, the bottom depths of the first and second vertical openings 15 and 16 may be increased.

The first vertical openings 15 and the second vertical openings 16 may be alternately disposed between the preliminary horizontal layers 14A in the second direction D2.

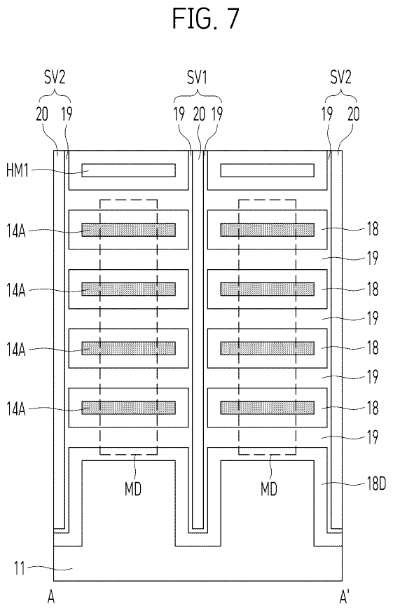

Referring to FIG. 7, first dielectric layers 18 covering the preliminary horizontal layers 14A may be formed. The first dielectric layers 18 may include silicon nitride. The first dielectric layers 18 may fully cover the upper surface, lower surface, and side surfaces of the preliminary horizontal layers 14A.

While the first dielectric layers 18 are formed, a dummy dielectric layer 18D may be formed on the surface of the lower structure 11. A portion of the first dielectric layers 18 may fully cover the upper surface, lower surface, and side surfaces of the hard mask layer pattern HM1.

A second dielectric layer 19 may be formed over the first dielectric layers 18. The second dielectric layer 19 may fill between the vertically neighboring first dielectric layers 18. The second dielectric layer 19 may include silicon oxide. Portions of the second dielectric layer 19 may be conformally formed on the surfaces of the first and second vertical openings 15 and 16. The horizontal recesses (17 in FIG. 6) may be filled with the first dielectric layer 18 and the second dielectric layer 19.

Sacrificial pillars 20 may be formed over the second dielectric layer 19 which is disposed in the first and second vertical openings 15 and 16. The sacrificial pillars 20 may include amorphous carbon as a sacrificial material. According to another embodiment of the present disclosure, a pillar capping layer may be further formed over the sacrificial pillars 20. The pillar capping layer may include a metal-based material. The pillar capping layer may include titanium nitride. The process of forming the sacrificial pillars 20 may include depositing a sacrificial material and planarizing the sacrificial material. The planarization process for forming the sacrificial pillars 20 may be performed until the uppermost-level first dielectric layer 18 is exposed. Subsequently, the uppermost-level second dielectric layers 19 may also be planarized until the uppermost-level first dielectric layer 18 is exposed. The sacrificial pillars 20 may not be formed between the first dielectric layers 18 that are vertically stacked.

The second dielectric layers 19 and the sacrificial pillars 20 may form first and second sacrificial pillar structures SV1 and SV2 that fill the first and second vertical openings 15 and 16. The first sacrificial pillar structure SV1 may fill the first vertical openings 15, and the second sacrificial pillar structure SV2 may fill the second vertical openings 16. According to another embodiment of the present disclosure, the first and second sacrificial pillar structures SV1 and SV2 may include a dielectric material, a carbon-containing material, a metal-based material, or a combination thereof. According to another embodiment of the present disclosure, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be hole-shaped sacrificial pillars. According to another embodiment of the present disclosure, portions of the first dielectric layer 18 may be conformally formed on the surfaces of the first and second vertical openings 15 and 16. Accordingly, the first and second sacrificial pillar structures SV1 and SV2 may further include the portions of the first dielectric layer 18.

As described above, as the preliminary horizontal layers 14A, the first dielectric layers 18, and the second dielectric layers 19 are formed, a cell mold structure MD may be formed. The cell mold structure MD may include a plurality of cell molds. Each cell mold may include a plurality of mold layers. The mold layers may refer to the preliminary horizontal layers 14A, the first dielectric layers 18, and the second dielectric layers 19. Each cell mold may include an Oxide-Nitride-Silicon-Nitride (ONSN) stack. Here, the ONSN stack may refer to a structure in which silicon oxide, a first silicon nitride, a monocrystalline silicon layer, and a second silicon nitride are sequentially stacked. The silicon oxide may correspond to the second dielectric layers 19. The first and second silicon nitrides may correspond to the first dielectric layers 18. The monocrystalline silicon layer may correspond to the preliminary horizontal layers 14A. A cell mold structure MD including a plurality of cell molds may be referred to as a vertical stack. From another perspective, the cell mold structure may include an Oxide-Nitride-Silicon-Nitride-Oxide (ONSNO) stack. Here, the ONSNO stack may refer to a structure in which a first silicon oxide, a first silicon nitride, a monocrystalline silicon layer, a second silicon nitride, and a second silicon oxide are sequentially stacked.

As described above, the sub-stacks of the stack body SB may be replaced with cell molds by a series of the processes illustrated in FIGS. 4 to 7. The first layers 12A, the second layers 13, and the third layers 12B of the stack body SB of FIG. 4 may be replaced with the first dielectric layers 18 and the second dielectric layers 19 of the cell mold structure MD of FIG. 7. The fourth layers 14 of the stack body SB may become the preliminary horizontal layers 14A of the cell mold structure MD by a recess process. The first dielectric layers 18 may be referred to as trimming target layers.

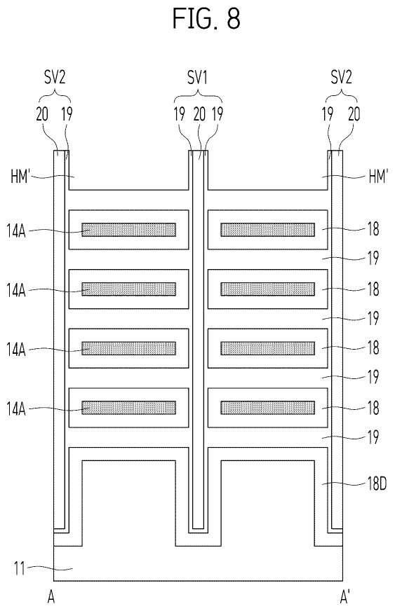

Referring to FIG. 8, the hard mask layer pattern HM1 and the uppermost-level first dielectric layer 18 may be removed to form a hard mask layer level opening HM′.

In some embodiments, before the hard mask layer level opening HM′ is formed, cell dielectric layers ISOA and ISOB as illustrated in FIG. 2 may be formed. Also, before the cell dielectric layers ISOA and ISOB are formed, a trimming process of the preliminary horizontal layers 14A may be performed. As a result of the trimming process, the preliminary horizontal layers 14A may have a shape in which a plurality of cross shapes is individually separated in the third direction D3.

For example, after the process of forming the cell mold structure MD is performed, forming the cell dielectric openings, trimming the preliminary horizontal layers 14A through the cell dielectric openings, and forming the cell dielectric layers to fill the cell dielectric openings may be sequentially performed. Also, before the process of forming the cell mold structure MD is performed, forming sacrificial dielectric openings in the stack body and forming sacrificial dielectric layers to fill the sacrificial dielectric openings may be performed. The sacrificial dielectric layers may be removed to form the cell dielectric openings.

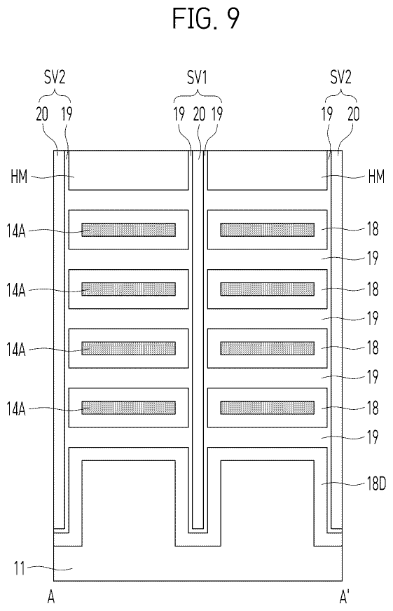

Referring to FIG. 9, the top dielectric layers HM may fill the hard mask layer level opening HM′. The top dielectric layers HM may include silicon oxide.

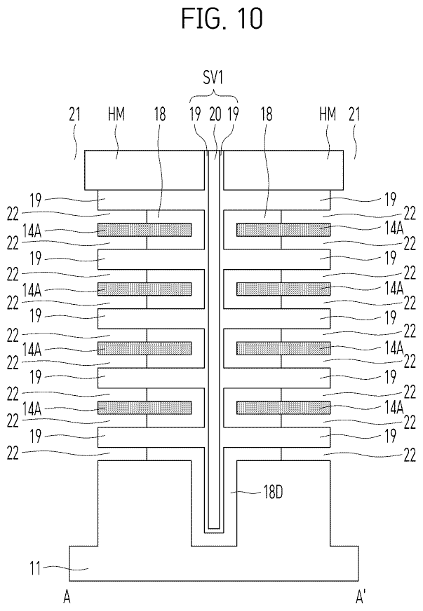

Referring to FIG. 10, the second sacrificial pillar structures SV2 of FIG. 9 may be removed to form sacrificial vertical openings 21. The second dielectric layer 19 and the sacrificial pillars 20 of the second sacrificial pillar structures SV2 may be selectively etched to form the sacrificial vertical openings 21.

The second dielectric layers 19 may be horizontally recessed through the sacrificial vertical openings 21. As a result, the first dielectric layers 18 and the dummy dielectric layer 18D may be exposed by the sacrificial vertical openings 21.

The first dielectric layers 18 and the dummy dielectric layer 18D may be selectively horizontally recessed. As a result, dielectric layer level recesses 22 may be formed, and portions of the preliminary horizontal layers 14A may be exposed by the dielectric layer level recesses 22.

The recessed amount of the first dielectric layers 18 may be greater than the recessed amount of the second dielectric layers 19.

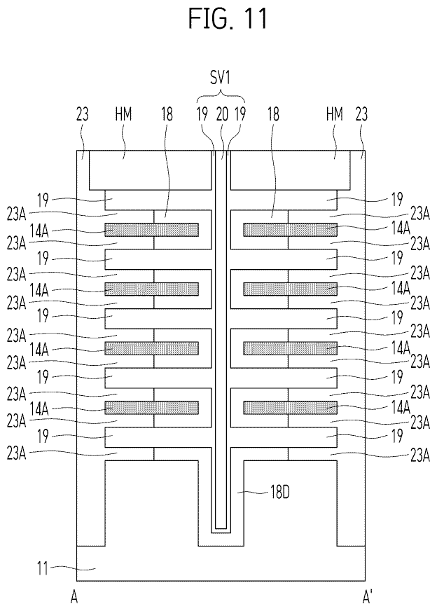

Referring to FIG. 11, vertical sacrificial structures 23 may be formed to fill the dielectric layer level recesses 22 and the sacrificial vertical openings 21 of FIG. 10. The vertical sacrificial structures 23 may include a dielectric material. The vertical sacrificial structures 23 may include silicon oxide, silicon nitride, titanium nitride, amorphous carbon, or a combination thereof. Each of the vertical sacrificial structures 23 may include expanded portions 23A that fill the dielectric layer level recesses 22.

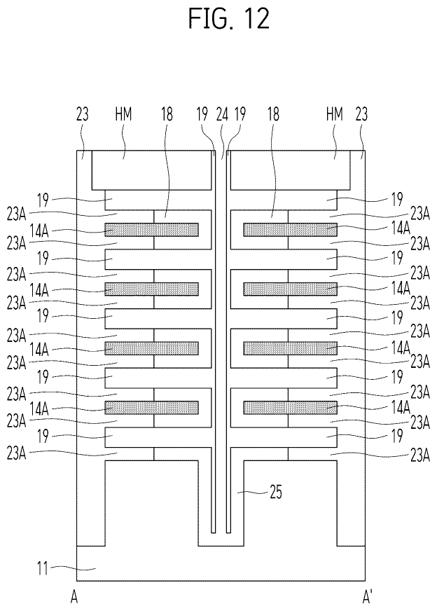

Referring to FIG. 12, the sacrificial pillars 20 of the first sacrificial pillar structure SV1 of FIG. 11 may be removed to form a vertical level path 24.

The dummy dielectric layer 18D below the vertical level path 24 may be removed to form a lower level gap 25. Before removing the dummy dielectric layer 18D, the bottom surface of the lowermost-level second dielectric layer 19 may be cut.

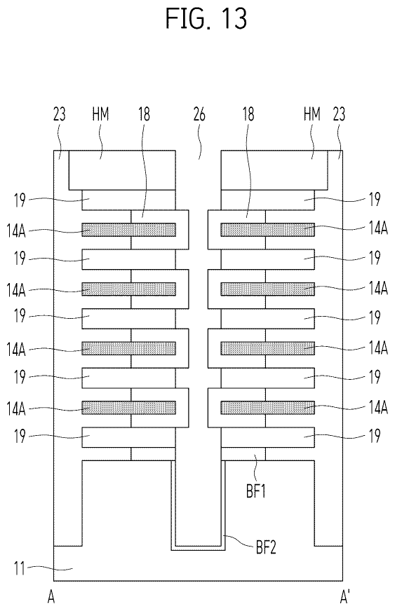

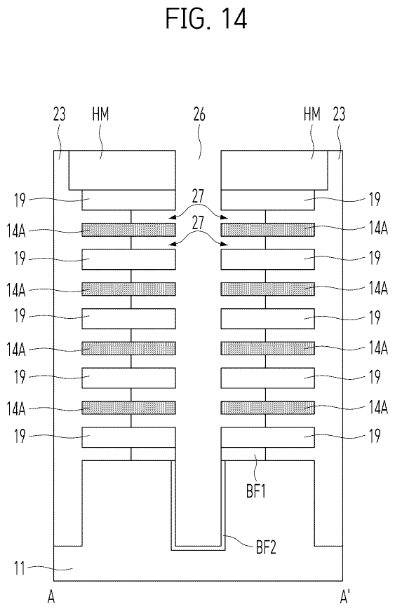

Referring to FIG. 13, the second dielectric layers 19 may be cut to form first hole-shaped vertical openings 26.

A first passivation layer BF1 filling the lower level gap 25 may be formed. The first passivation layer BF1 may include silicon oxide. The process of forming the first passivation layer BF1 may include depositing silicon oxide to fill the lower level gap 25 and etching the silicon oxide.

A second passivation layer BF2 may be formed in the lower regions of the first hole-shaped vertical openings 26. For example, the surface of the lower structure 11 may be oxidized to form the second passivation layer BF2.

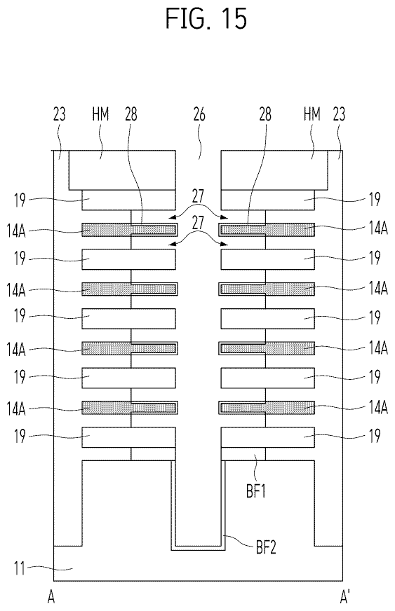

Referring to FIG. 14, the first dielectric layers 18 of FIG. 13 may be removed to form horizontal level recesses 27 extending from the first hole-shaped vertical openings 26. Portions of the preliminary horizontal layers 14A may be exposed by the horizontal level recesses 27. A pair of the horizontal level recesses 27 may partially expose one preliminary horizontal layer 14A. The horizontal level recesses 27 may be disposed between the second dielectric layer 19 and the preliminary horizontal layers 14A. Two horizontal level recesses 27 may face each other with one preliminary horizontal layer 14A interposed therebetween.

Referring to FIG. 15, an inter-level dielectric layer 28 may be formed over the exposed portions of the preliminary horizontal layers 14A. The inter-level dielectric layer 28 may be referred to as a gate dielectric layer. The inter-level dielectric layer 28 may correspond to the inter-level dielectric layer GD illustrated in FIGS. 1A to 1C. The inter-level dielectric layer 28 may be formed by oxidizing the surface of the preliminary horizontal layers 14A. According to another embodiment of the present disclosure, the inter-level dielectric layer 28 may be formed by a process of depositing silicon oxide.

The inter-level dielectric layer 28 may include silicon oxide, silicon nitride, a metal oxide, a metal oxynitride, a metal silicate, a high-k material, a ferroelectric material, an anti-ferroelectric material, or a combination thereof. The inter-level dielectric layer 28 may include SiO₂, Si₃N₄, HfO₂, Al₂O₃, ZrO₂, AlON, HfON, HfSiO, HfSiON, or a combination thereof.

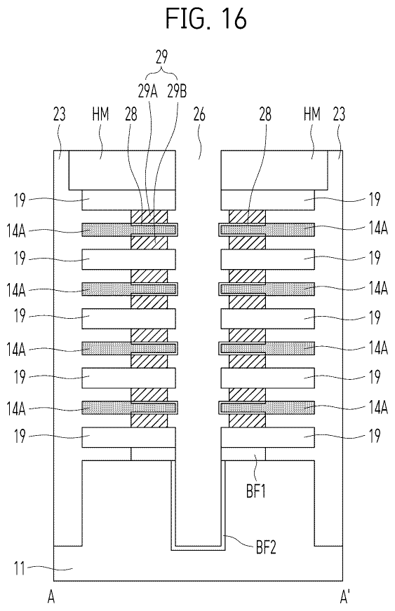

Referring to FIG. 16, a horizontal conductive line 29 may be formed over the inter-level dielectric layer 28 to fill the horizontal level recesses 27 of FIG. 15. The process of forming the horizontal conductive line 29 may include depositing a conductive material to fill the horizontal level recesses 27 over the inter-level dielectric layer 28 and performing an etch-back process on the conductive material. The horizontal conductive line 29 may include a pair of a first horizontal conductive line 29A and a second horizontal conductive line 29B that are facing each other with the preliminary horizontal layer 14A interposed therebetween. The first and second horizontal conductive lines 29A and 29B may include a metal-based material, a semiconductor material, or a combination thereof. The first and second horizontal conductive lines 29A and 29B may include titanium nitride, tungsten, polysilicon, or a combination thereof. For example, the first and second horizontal conductive lines 29A and 29B may include a titanium nitride and tungsten (TiN/W) stack in which titanium nitride and tungsten are sequentially stacked. The first and second horizontal conductive lines 29A and 29B may include an N-type work function material or a P-type work function material. The N-type work function material may have a low work function of approximately 4.5 eV or less. The P-type work function material may have a high work function of approximately 4.5 eV or greater.

The horizontal conductive line 29 may correspond to the second conductive line DWL as illustrated in FIGS. 1A to 1C. The first and second horizontal conductive lines 29A and 29B may correspond to the upper horizontal line G1 and the lower horizontal line G2 of FIGS. 1A to 1C. As illustrated in FIGS. 1A to 1C, each of the first and second horizontal conductive lines 29A and 29B may have a cross shape and may include a channel overlapping portion WLP and channel non-overlapping portions NOL.

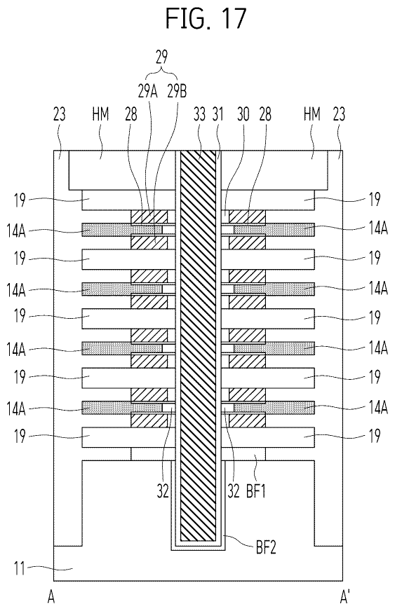

Referring to FIG. 17, a first capping layer 30 may be formed on one side of the horizontal conductive line 29. The first capping layer 30 may include silicon oxide, silicon nitride, silicon carbon oxide, an embedded air gap, or a combination thereof. The deposition of a capping material and the etch-back process of the capping material may be performed to form the first capping layer 30. While the first capping layer 30 is formed or after the first capping layer 30 is formed, a portion of the inter-level dielectric layer 28 may be removed to expose a first edge portion of each of the preliminary horizontal layers 14A.

A vertical conductive line 33 may be formed to be coupled to the first edge portion of each of the preliminary horizontal layers 14A. The vertical conductive line 33 may fill the first hole-shaped vertical openings 26 of FIG. 16. The vertical conductive line 33 may be commonly coupled to the preliminary horizontal layers 14A that are disposed in the first direction D1. The vertical conductive line 33 may include titanium nitride, tungsten, or a combination thereof. The vertical conductive line 33 may also be referred to as a bit line or a vertical bit line.

Before the vertical conductive line 33 is formed, a first doped region 32 and a first contact node 31 may be formed. The first doped region 32 may be formed in the first edge portion of the preliminary horizontal layers 14A. The process of forming the first doped region 32 may include depositing polysilicon that is doped with an N-type impurity, performing a heat treatment on the doped polysilicon, and removing the heat-treated doped polysilicon. The first doped region 32 may include the impurity diffused from the doped polysilicon. According to another embodiment of the present disclosure, the first doped region 32 may be formed by an impurity doping process.

The first contact node 31 may include doped polysilicon. The first doped region 32 may include the impurity diffused from the first contact node 31. A metal silicide layer may be further formed between the vertical conductive line 33 and the first contact node 31.

The vertical conductive line 33 may correspond to the first conductive line BL as illustrated in FIGS. 1A to 1C. The first contact node 31 may correspond to the first contact node BLC as illustrated in FIGS. 1A to 1C, and the first doped region 32 may correspond to the first doped region SR as illustrated in FIGS. 1A to 1C.

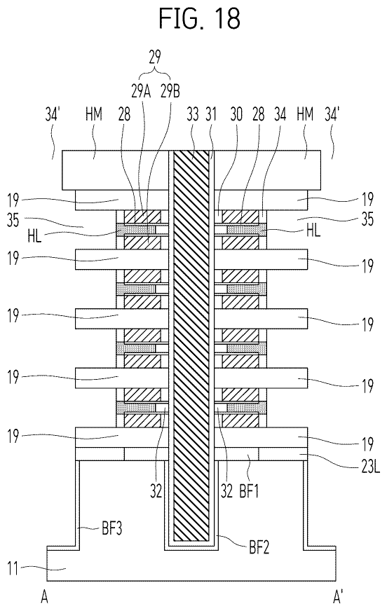

Referring to FIG. 18, a portion of the vertical sacrificial structure 23 of FIG. 17 may be removed to form the second hole-shaped vertical openings 34′. One side surface of the preliminary horizontal layers 14A, i.e., a second edge portion, may be exposed by the second hole-shaped vertical openings 34′.

By removing a portion of the vertical sacrificial structure 23, a lowermost-level dielectric layer 23L may be formed on the side surface of the first passivation layers BF1. According to another embodiment of the present disclosure, the lowermost-level dielectric layer 23L may not remain.

A third passivation layer BF3 may be formed on the surface of the lower structure 11. The third passivation layer BF3 may include silicon oxide. The third passivation layer BF3 may be formed, for example, by an oxidation process.

The second edge portion of the preliminary horizontal layers 14A may be horizontally recessed in the second direction D2, and as a result, horizontal layers HL may be formed.

Second capping layers 34 may be formed by selectively recessing the expanded portions (see ‘23A’ of FIG. 12) of the vertical sacrificial structure 23. The second capping layers 34 may include silicon oxide, silicon nitride, or a combination thereof.

After the second capping layers 34 are formed, storage openings 35 extending horizontally from the second hole-shaped vertical openings 34′ may be formed. The storage openings 35 may be referred to as capacitor openings.

The horizontal layers HL may include a first edge and a second edge. The first edge may refer to a portion that is coupled to the first contact node 31 and the vertical conductive line 33. The second edge may refer to a portion that is exposed by the storage openings 35.

The storage openings 35 may be disposed between the vertically neighboring second dielectric layers 19. The second capping layers 34 may be disposed in the lower and upper portions of the horizontal layers HL, respectively.

As described above, the process of forming the horizontal layers HL and the storage openings 35 may include forming the second hole-shaped vertical openings 34′, recessing the preliminary horizontal layers 14A, and forming the second capping layers 34.

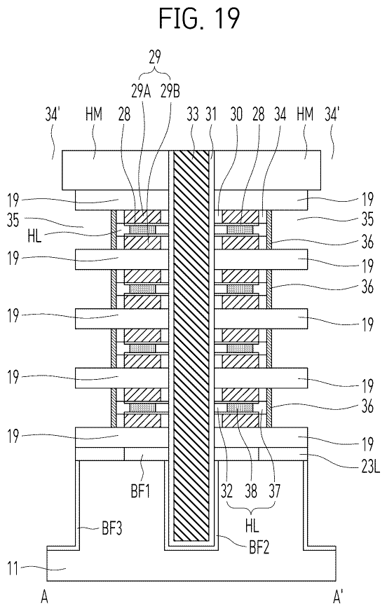

Referring to FIG. 19, second doped regions 37 may be formed respectively in the second edges of the horizontal layers HL. The process of forming the second doped regions 37 may include depositing polysilicon that is doped with an N-type impurity, performing a heat treatment on the doped polysilicon, and removing the heat-treated doped polysilicon. The second doped regions 37 may include the impurity diffused from the doped polysilicon. According to another embodiment of the present disclosure, the doped polysilicon may remain after the heat treatment is performed.

Second contact nodes 36 may be formed over the second edges of the horizontal layers HL. The second contact nodes 36 may include doped polysilicon. The second doped regions 37 may include the impurity diffused from the second contact nodes 36.

Each of the horizontal layers HL may include a first doped region 32, a second doped region 37, and a channel 38 that are disposed horizontally in the second direction D2. Each of the channels 38 may be defined between each of the first doped regions 32 and each of the second doped regions 37. The channels 38 may vertically overlap with the horizontal conductive lines 29. As illustrated in FIGS. 1A to 1C, the horizontal layers HL may have a cross shape, and the channels 38 may also have a cross shape.

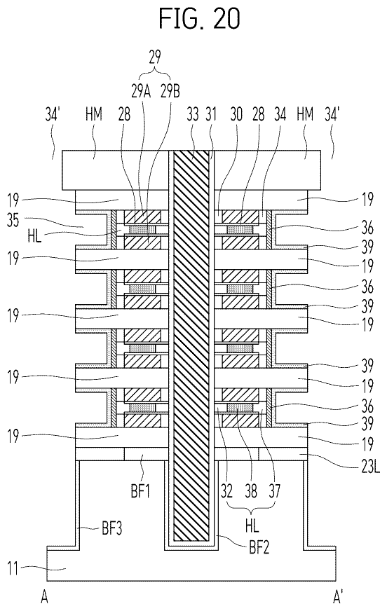

Referring to FIG. 20, first electrodes 39 of a data storage element may be formed over the second contact nodes 36. The first electrodes 39 may have a horizontally oriented cylindrical shape. The first electrodes 39 may be respectively disposed in the storage openings 35. The first electrodes 39 that are disposed adjacent to each other in the second direction D2 may be spaced apart from each other by the second hole-shaped vertical openings 34′.

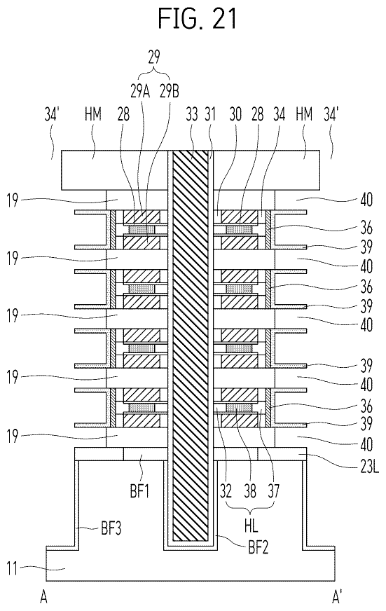

Referring to FIG. 21, the second dielectric layers 19 may be horizontally recessed (see a reference numeral ‘40’). As a result, the outer walls of the first electrodes 39 may be exposed. The recessed second dielectric layers 19 may correspond to an inter-cell dielectric layer IL as illustrated in FIG. 3B.

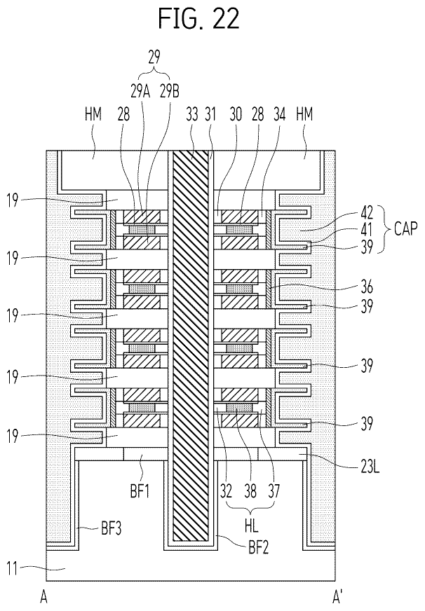

Referring to FIG. 22, a dielectric layer 41 and a second electrode 42 may be sequentially formed over the first electrodes 39. The first electrode 39, the dielectric layer 41, and the second electrode 42 may form a data storage element CAP.

The first electrode 39 may include an inner space and a plurality of outer surfaces. The inner space of the first electrode 39 may include a plurality of inner surfaces. The outer surfaces of the first electrode 39 may include vertical outer surfaces and a plurality of horizontal outer surfaces. The inner space of the first electrode 39 may be a three-dimensional space. The dielectric layer 41 may conformally cover the inner surfaces and the outer surfaces of the first electrode 39. The second electrode 42 may be disposed in the inner space of the first electrode 39 over the dielectric layer 41. Some of the outer surfaces of the first electrode 39 may be coupled to the horizontal layer HL.

The first electrode 39 may have a cylindrical shape. The cylindrical shape of the first electrode 39 may include cylindrical inner surfaces and cylindrical outer surfaces. The dielectric layer 41 and the second electrode 42 may be disposed on the cylindrical inner surfaces of the first electrode 39.

The first electrode 39 and the second electrode 42 may include a metal, a noble metal, a metal nitride, a conductive metal oxide, a conductive noble metal oxide, a metal carbide, a metal silicide, or a combination thereof. For example, the first electrode 39 and the second electrode 42 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 42 may also include a combination of a metal-based material and a silicon-based material. For example, the second electrode 42 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inner space of the first electrode 39, the titanium nitride (TIN) may serve as the second electrode 42 of the data storage element CAP, and the tungsten nitride may be a low-resistance material.

The dielectric layer 41 may be referred to as a capacitor dielectric layer or a memory layer. The dielectric layer 41 may include silicon oxide, silicon nitride, a high-k material, a ferroelectric material, an anti-ferroelectric material, or a combination thereof. The dielectric layer 41 may include a high-dielectric material, such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 41 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack.

According to another embodiment of the present disclosure, an interface control layer for improving the leakage current may be further formed between the first electrode 39 and the dielectric layer 41. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 42 and the dielectric layer 41.

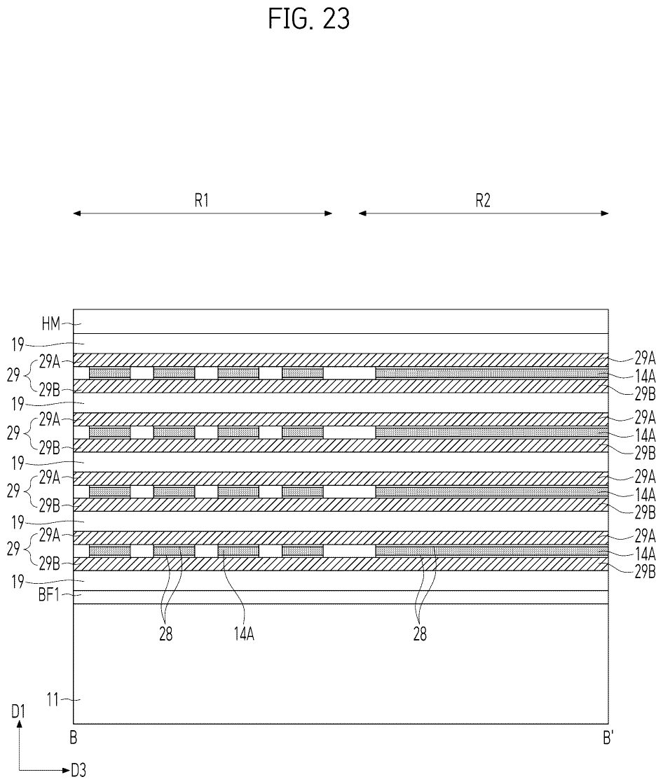

FIGS. 23 to 31 illustrate a method for forming a pad portion in accordance with an embodiment of the present disclosure. FIGS. 23 to 31 illustrate a method of forming a pad portion according to the line B-B′ of FIG. 2.

Referring back to FIGS. 4 to 17, after the horizontal conductive lines 29 and the vertical conductive line 33 are formed, the pad portion may be formed at an edge portion of one side of the horizontal conductive lines 29.

Referring to FIG. 23, the horizontal conductive lines 29 may include a pair of the first horizontal conductive line 29A and the second horizontal conductive line 29B. A plurality of horizontal conductive lines 29 may be stacked in the first direction D1. The preliminary horizontal layer 14A and the inter-level dielectric layer 28 may be formed in the first region R1 and the second region R2, respectively. Second dielectric layers 19 may be formed between the horizontal conductive lines 29, between the top dielectric layer HM and the uppermost horizontal conductive line 29, and between the lowermost horizontal conductive line 29 and the first passivation layer BF1.

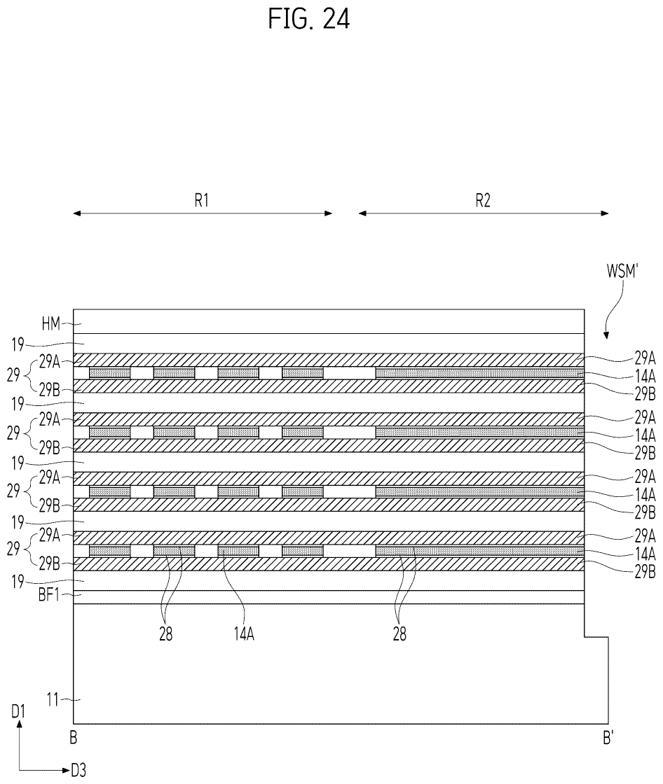

Referring to FIG. 24, a pad isolation slit WSM′ may be formed in the second region R2 by etching the top dielectric layer HM, the horizontal conductive lines 29, and the second dielectric layers 19.

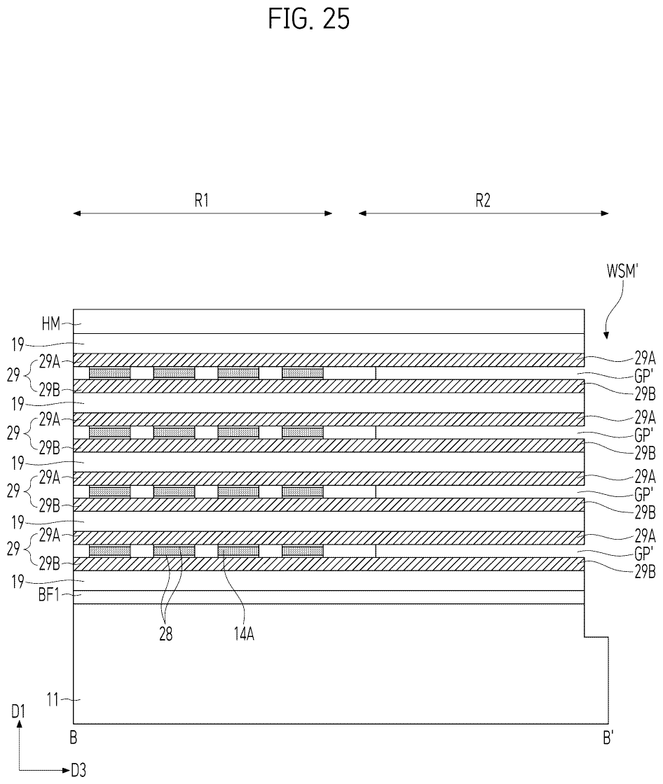

Referring to FIG. 25, the inter-level dielectric layer 28 and the preliminary horizontal layers 14A of FIG. 24 may be removed through the pad isolation slit WSM′ in the second region R2. As a result, pad-shaped recesses GP′ may be formed between the first horizontal conductive line 29A and the second horizontal conductive line 29B.

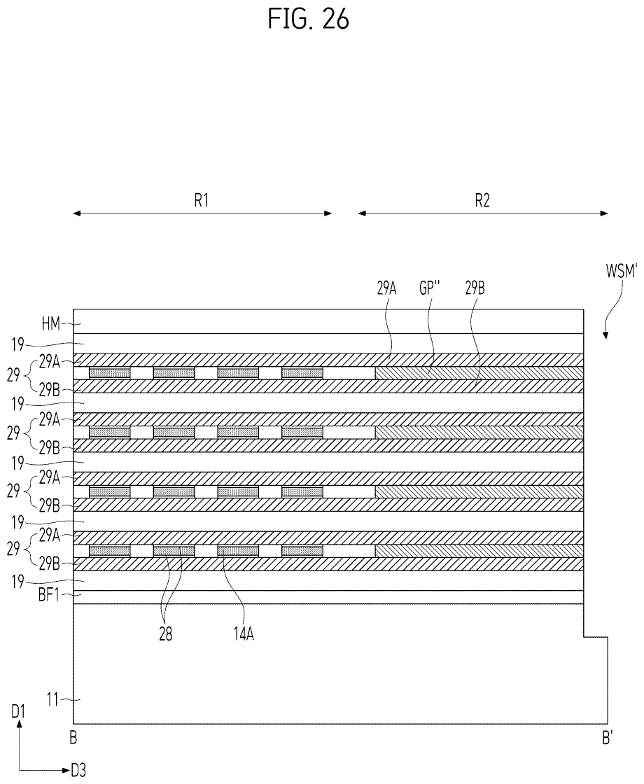

Referring to FIG. 26, pad materials GP″ may be formed to fill the pad-shaped recesses GP′ of FIG. 25. The pad materials GP″, the first horizontal conductive lines 29A and the second horizontal conductive lines 29B may include the same material. The pad materials GP″, the first horizontal conductive lines 29A and the second horizontal conductive lines 29B may include a metal-based material. For example, the pad materials GP″, the first horizontal conductive lines 29A and the second horizontal conductive lines 29B may include titanium nitride, tungsten or a combination thereof. They may include a metal-based material.

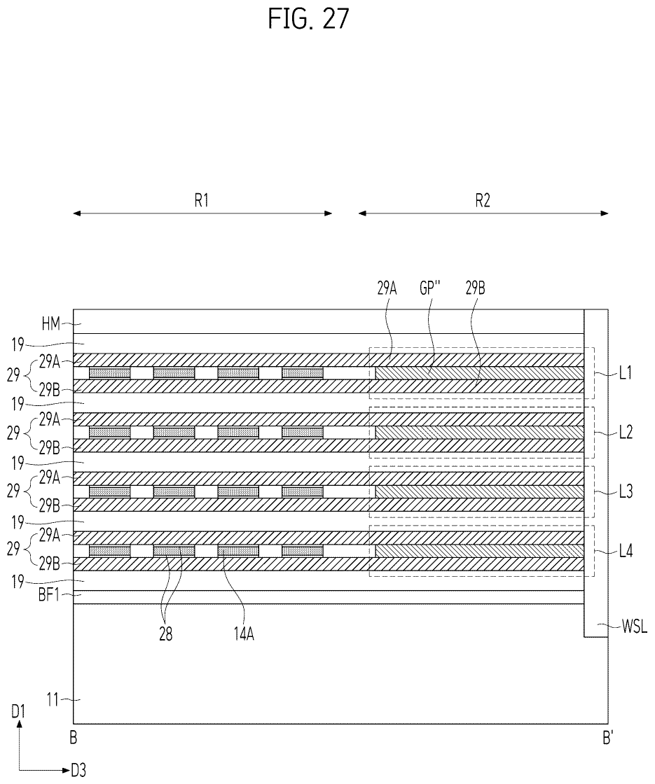

Referring to FIG. 27, isolation slits WSL may be formed to fill the pad isolation slits WSM′ of FIG. 26.

The horizontal conductive lines 29 in the second region R2 described above may include a plurality of levels L1, L2, L3 and L4. For example, the first level L1 may refer to the uppermost-level horizontal conductive line 29, and the fourth level L4 may refer to the lowermost-level horizontal conductive line 29. The second level L2 may be a level lower than the first level L1, and the third level L3 may be a level lower than the second level L2. The fourth level L4 may be a level lower than the third level L3.

The fourth level L4, the third level L3, the second level L2, and the first level L1 may be sequentially stacked in the first direction D1.

Each of the horizontal conductive lines 29 of the levels L1 to L4 may include a pair of the first horizontal conductive line 29A and the second horizontal conductive line 29B. The horizontal conductive lines 29 may be disposed in the first region R1, and portions of the horizontal conductive lines 29 may extend to the second region R2. Portions of the horizontal conductive lines 29 disposed in the second region R2 may be simply referred to as an edge portion or a pad portion.

The pad portion of the horizontal conductive lines 29 may include a plurality of levels L1, L2, L3 and L4. In the pad portion, each of the horizontal conductive lines 29 of the levels L1 to L4 may include a pair of the first horizontal conductive line 29A and the second horizontal conductive line 29B. The levels L1 to L4 in the pad portion may further include the pad materials GP″. The pad materials GP″ may be disposed between the first horizontal conductive line 29A and the second horizontal conductive line 29B. The pad materials GP″ may be electrically connected to the first horizontal conductive line 29A and the second horizontal conductive line 29B.

The horizontal lengths of the pad materials GP″ in the third direction D3 may be the same. The pad materials GP″ and the preliminary horizontal layers 14A may be spaced apart from each other. The pad materials GP″ may not be disposed in the first region R1.

The pad portion of the horizontal conductive lines 29 may include a plurality of levels L1, L2, L3 and L4, and the pad portion may be referred to as a mold stack.

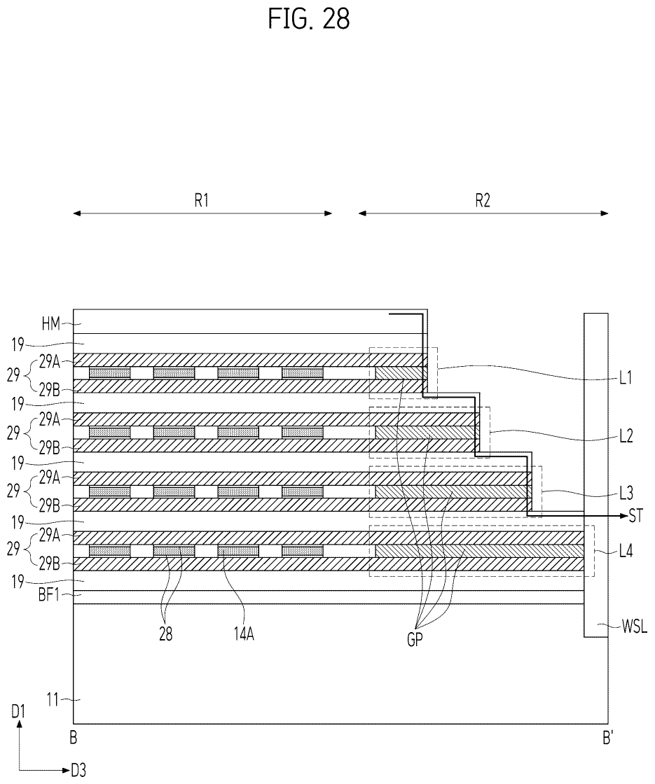

Subsequently, referring to FIGS. 28 to 31, a plurality of contact structures CT1 to CT4 may be formed in the second region R2.

Referring to FIG. 28, a portion of the pad portion in the second region R2 may be etched to form a stair structure ST. The stair structure ST may be formed in the second region R2 by sequentially etching the horizontal conductive lines 29 of the levels L1 to L4 and the pad materials GP″. For example, the stair structure ST may be formed by repeatedly performing a masking process and an etching process several times.

After the stair structure ST is formed, a plurality of pads GP may be formed. The pads GP of the levels L1 to L4 may have different horizontal lengths. The horizontal lengths of the pads GP may be gradually increased in the first direction D1.

As described above, according to the embodiment of the present disclosure, after the horizontal conductive lines 29 and the pad materials GP″ are formed in the second region R2, a pad etching process for forming the stair structure ST may be performed.

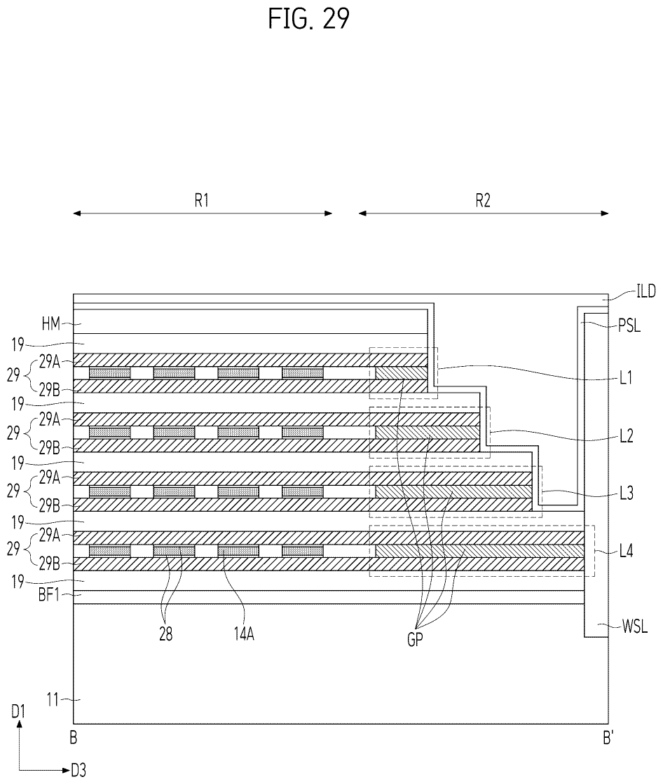

Referring to FIG. 29, a pad passivation layer PSL may be conformally formed over the stair structure ST. The pad passivation layer PSL may include silicon nitride.

An inter-layer dielectric layer ILD may be formed over the pad passivation layer PSL. The inter-layer dielectric layer ILD may include silicon oxide.

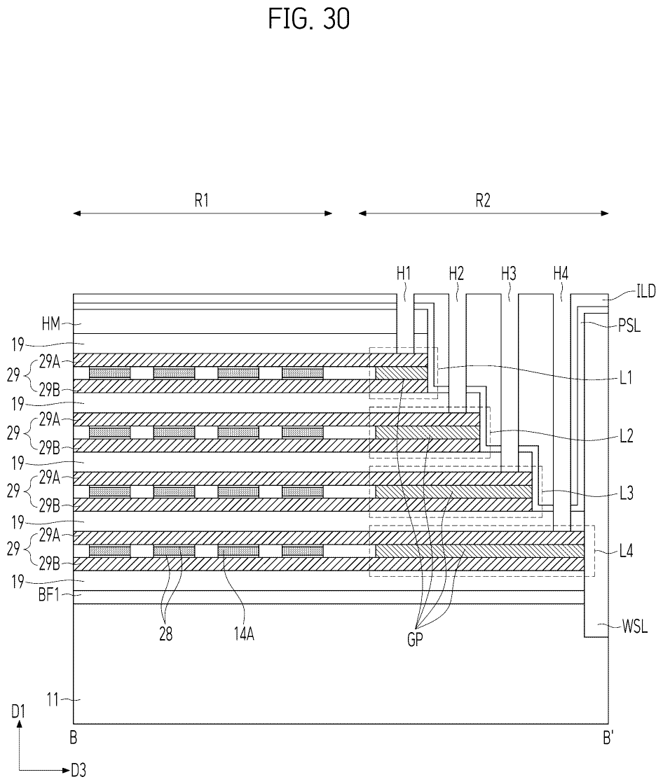

Referring to FIG. 30, a plurality of contact holes H1 to H4 may be formed to expose the horizontal conductive lines 29 of the levels L1 to L4 in the second region R2.

The contact holes H1 to H4 may expose the upper surface of the horizontal conductive line 29 of each level L1 to L4, i.e., the upper surface of the first horizontal conductive line 29A.

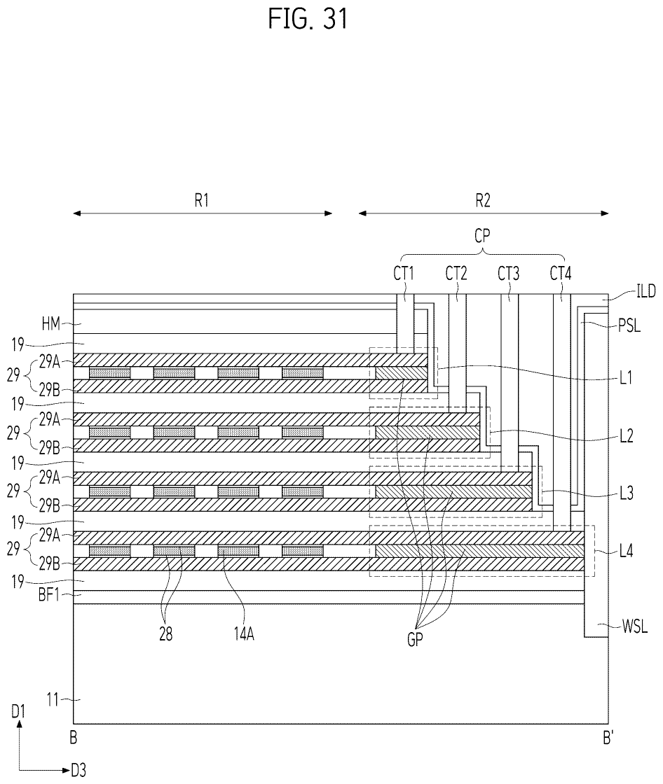

Referring to FIG. 31, the contact plugs CT1 to CT4 may be formed in the contact holes H1 to H4, respectively. The contact plugs CT1 to CT4 may include a metal-based material. The contact plugs CT1 to CT4 may have a structure in which the vertical heights of the contact plugs CT1 to CT4 are gradually decreased in a direction that the horizontal conductive lines 29 are stacked (i.e., the first direction D1).

As described above, the second region R2 may include the contact structures CP respectively coupled to the horizontal conductive lines 29 of the pad portion. The contact structures CP may include contact plugs CT1 to CT4.

The first contact plug CT1 may be electrically connected to the horizontal conductive line 29 of the first level L1. The first contact plug CT1 may be electrically connected to the first horizontal conductive line 29A of the first level L1. The second contact plug CT2 may be electrically connected to the horizontal conductive line 29 of the second level L2. The second contact plug CT2 may be electrically connected to the first horizontal conductive line 29A of the second level L2. The third contact plug CT3 may be electrically connected to the horizontal conductive line 29 of the third level L3. The third contact plug CT3 may be electrically connected to the first horizontal conductive line 29A of the third level L3. The fourth contact plug CT4 may be electrically connected to the horizontal conductive line 29 of the fourth level L4. The fourth contact plug CT4 may be electrically connected to the first horizontal conductive line 29A of the fourth level L4.

The vertical height of the fourth contact plug CT4 may be greater than the vertical height of the third contact plug CT3. The vertical height of the third contact plug CT3 may be greater than the vertical height of the second contact plug CT2. The vertical height of the second contact plug CT2 may be greater than the vertical height of the first contact plug CT1. Here, the vertical height may refer to the height in the first direction D1.

As described above, the pad portion of the horizontal conductive lines 29 may have a stair structure.

According to the embodiment of the present disclosure, the pad portion of the horizontal conductive lines may be formed in a stair structure. However, since the pad etching process is performed after a pad material is formed, the contact margin of the pad portion may be improved.

Also, since a metal-based material and silicon oxide are etched during the pad etching process in accordance with the embodiment of the present disclosure, the pad etching process may be performed easily.

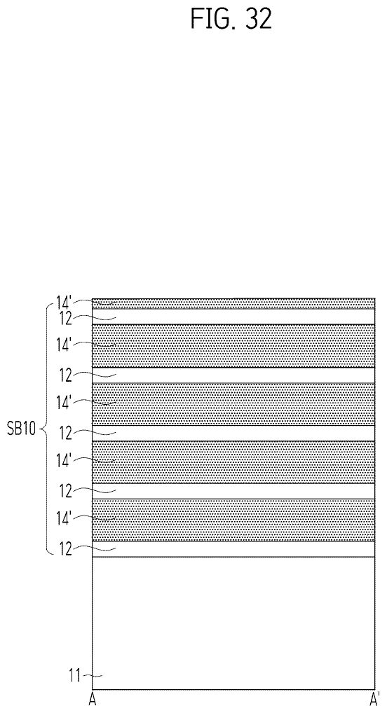

FIGS. 32 to 34 are schematic cross-sectional views illustrating a method for fabricating a semiconductor device in accordance with another embodiment of the present disclosure.

Referring to FIG. 32, a stack body SB10 may be formed over a lower structure 11. The stack body SB10 may include an alternating stack of first semiconductor layers and second semiconductor layers. For example, the alternating stack may include a plurality of silicon germanium layers 12 and a plurality of monocrystalline silicon layers 14′ that are alternately stacked by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B of FIG. 4, and the monocrystalline silicon layers 14′ may correspond to the fourth layers 14 of FIG. 4. Unlike the stack body SB of FIG. 4, the stack body SB10 may be formed of an alternating stack of the silicon germanium layers 12 and the monocrystalline silicon layers 14′.

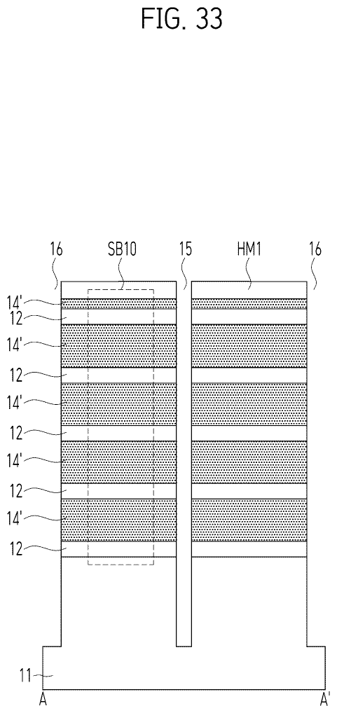

Referring to FIG. 33, a hard mask layer pattern HM1 may be formed over the stack body SB10.

The stack body SB10 may be etched by using the hard mask layer pattern HM1 as an etching barrier. As a result, a plurality of first and second vertical openings 15 and 16 may be formed in the stack body SB10.

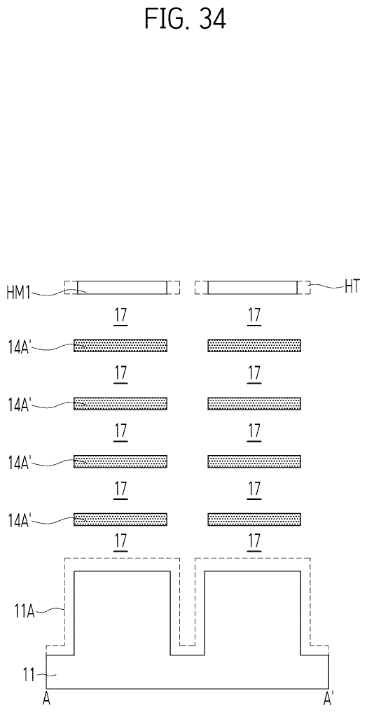

Referring to FIG. 34, preliminary horizontal layers 14A′ and horizontal recesses 17 may be formed. The preliminary horizontal layers 14A′ and the horizontal recesses 17 may be formed by a recess process of the silicon germanium layers 12 and the monocrystalline silicon layers 14′ of FIG. 42. After the silicon germanium layers 12 are removed, a process of recessing the monocrystalline silicon layers 14′ may be performed. The preliminary horizontal layers 14A′ may correspond to the preliminary horizontal layers 14A of FIG. 6.

The silicon germanium layers 12 may be recessed by a wet etching process or a dry etching process. The silicon germanium layers 12 may be etched by using an etchant or etching gas having a selectivity with respect to the monocrystalline silicon layers 14′.

The recess process of the monocrystalline silicon layers 14′ for forming the preliminary horizontal layers 14A′ may use, for example, Hot SC-1 (HSC1). HSC1 may include a solution in which ammonium hydroxide (NH₄OH), hydrogen peroxide (H₂O₂), and water (H₂O) are mixed in a ratio of approximately 1:4:20. The monocrystalline silicon layers 14′ may be selectively etched by using the HSC1.

While the preliminary horizontal layers 14A′ are formed, the surface of the lower structure 11 may be recessed to a predetermined depth (see a reference numeral ‘11A’). As a result, the depth of the first and second vertical openings 15 and 16 may be increased.

Subsequently, a series of the processes illustrated in FIGS. 8 to 22 may be performed.

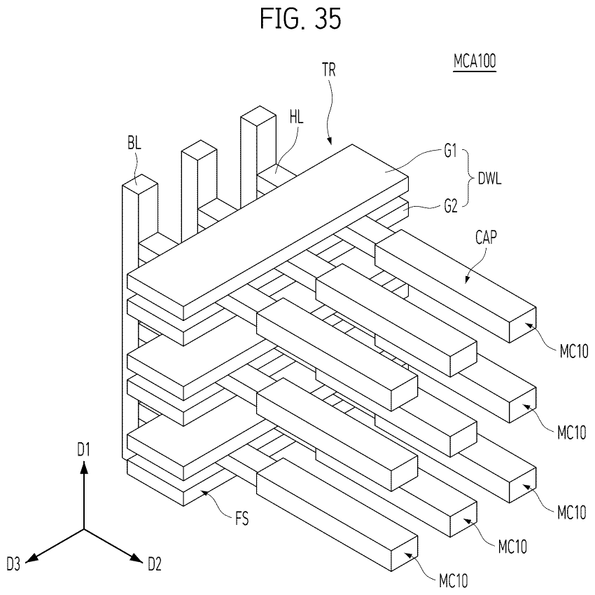

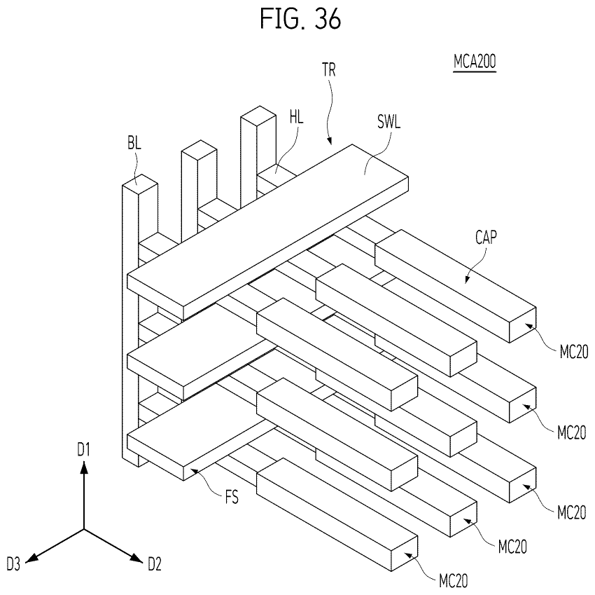

FIGS. 35 to 37 are perspective views illustrating memory cell arrays in accordance with other embodiments of the present disclosure. The memory cell arrays MCA100, MCA200 and MCA300 may be similar to those of FIGS. 2 to 3D. Hereinafter, as for the detailed description on the constituent elements also appearing in FIGS. 2 to 3D, the above-described embodiments of the present disclosure may be referred to.

Each of the memory cell arrays MCA100, MCA200 and MCA300 may include a first region R1 and a second region R2, as illustrated in FIGS. 2 to 3D. The first region R1 may be a region where memory cells are disposed, and the second region R2 may be a region where pad portions are disposed.

FIGS. 35 to 37 illustrate three-dimensional arrays of memory cells formed in the first region.

Referring to FIG. 35, the memory cell array MCA100 may include a plurality of memory cells MC10.

The memory cell array MCA100 may include a three-dimensional array of memory cells MC10. The three-dimensional array of the memory cells MC10 may include a column array of memory cells MC10 and a row array of memory cells MC10. The column array of the memory cells MC10 may include a plurality of memory cells MC10 that are stacked in the first direction D1. The row array of the memory cells MC10 may include a plurality of memory cells MC10 that are horizontally disposed in the second direction D2 and the third direction D3.

Each memory cell MC10 may include a first conductive line BL, a switching element TR, and a data storage element CAP. As for the detailed description the first conductive line BL and the data storage element CAP, the above-described embodiments of the present disclosure may be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G2 that are facing each other with the horizontal layer HL interposed therebetween. As illustrated in FIGS. 1B and 3B, an inter-level dielectric layer GD may be formed on the upper surface and the lower surface of the horizontal layer HL.

Each of the upper horizontal line G1 and the lower horizontal line G2 may include a pair of flat sidewalls FS extending in the third direction D3. The flat sidewalls FS may refer to vertical sidewalls. The flat sidewalls FS may have a linear shape extending in the third direction D3.

Referring to FIG. 36, the memory cell array MCA200 may include a plurality of memory cells MC20.

The memory cell array MCA200 may include a three-dimensional array of memory cells MC20. The three-dimensional array of the memory cells MC20 may include a column array of memory cells MC20 and a row array of memory cells MC20. The column array of the memory cells MC20 may include a plurality of memory cells MC20 that are stacked in the first direction D1. The row array of the memory cells MC20 may include a plurality of memory cells MC20 that are horizontally disposed in the second direction D2 and the third direction D3.

Each memory cell MC20 may include a first conductive line BL, a switching element TR, and a data storage element CAP. As for the detailed description on the first conductive line BL and the data storage element CAP, the above-described embodiments of the present disclosure may be referred to.

The switching element TR may include a horizontal layer HL and a second conductive line SWL. The horizontal layer HL may extend in the second direction D2. The second conductive line SWL may extend in the third direction D3.

The second conductive line SWL may have a single structure. For example, the second conductive line SWL may be disposed over the horizontal layer HL. As illustrated in FIGS. 1B and 3B, an inter-level dielectric layer GD may be formed between the upper surface of the horizontal layer HL and the second conductive line SWL. According to another embodiment of the present disclosure, the second conductive line SWL may be disposed below the horizontal layer HL.

The second conductive line SWL may include a pair of flat sidewalls FS extending in the third direction D3. The flat sidewalls FS may refer to vertical sidewalls.

According to another embodiment of the present disclosure, the second conductive line SWL may include a channel overlapping portion WLP and a channel non-overlapping portion NOL, as illustrated in FIG. 1C.

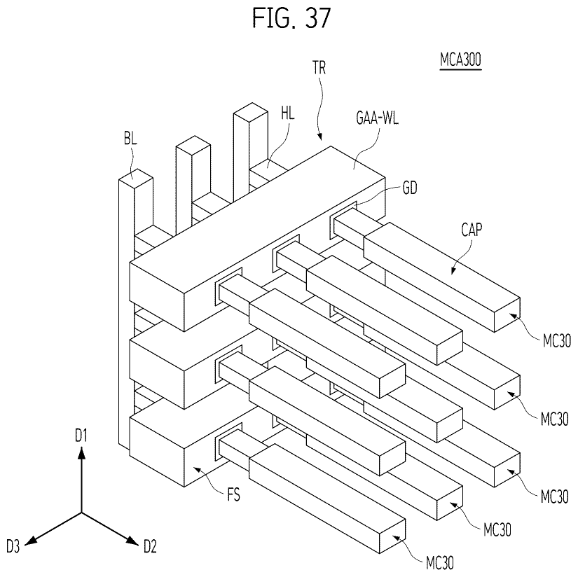

Referring to FIG. 37, the memory cell array MCA300 may include a plurality of memory cells MC30.

The memory cell array MCA300 may include a three-dimensional array of memory cells MC30. The three-dimensional array of the memory cells MC30 may include a column array of memory cells MC30 and a row array of memory cells MC30. The column array of the memory cells MC30 may include a plurality of the memory cells MC30 that are stacked in the first direction D1. The row array of the memory cells MC30 may include a plurality of the memory cells MC30 that are horizontally disposed in the second direction D2 and the third direction D3.

Each memory cell MC30 may include a first conductive line BL, a switching element TR, and a data storage element CAP. As for the detailed description of the first conductive line BL and the data storage element CAP, the above-described embodiments of the present disclosure may be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may have a gate all around structure. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat sidewalls FS extending in the third direction D3. The flat sidewalls FS may refer to vertical sidewalls.

According to another embodiment of the present disclosure, each memory cell may include a first conductive line BL extending horizontally in the third direction D3, a second conductive line DWL extending vertically in the first direction D1, and a horizontal layer HL extending horizontally in the second direction D2. The second conductive line DWL may have a double structure and may be replaced with a single structure or a gate-all-around structure.

According to another embodiment of the present disclosure, the semiconductor device may include a plurality of first conductive layers 29 that are vertically stacked in the first direction D1 over a lower structure 11 of a first region R1, and a plurality of contact structures CP including a plurality of second conductive layers L1 to L4 that are stacked in the first direction D1 over the lower structure 11 of a second region R2 and having the same horizontal length, and coupled to the second region R2 and the second conductive layers L1 to L4, respectively. Each of the second conductive layers L1 to L4 may include a first horizontal conductive line 29A, a second horizontal conductive line 29B, and a pad GP between the first horizontal conductive line 29A and the second horizontal conductive line 29B. The horizontal lengths of the first horizontal conductive line 29A, the second horizontal conductive line 29B, and the pad GP in the third direction D3 may be different from each other. The first conductive layers 29 may further include a first horizontal conductive line 29A, a second horizontal conductive line 29B, and a horizontal layer HL between the first horizontal conductive line 29A and the second horizontal conductive line 29B. The first conductive layers 29 may correspond to the horizontal conductive lines 29 of FIG. 31, and the second conductive layers L1 to L4 may correspond to the levels L1 to L4 of FIG. 31.

According to the embodiments of the present disclosure, the contact margin of the pad portion of the horizontal conductive lines may be improved by forming the pad portion in a stair structure and performing a pad etching process after a pad material is formed.

Also, according to the embodiments of the present disclosure, since a metal-based material and silicon oxide are etched, the pad may be etched easily during the pad etching process.

While the embodiments of the present disclosure have been described with respect to the specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A method for fabricating a semiconductor device, the method comprising:
forming a mold stack of conductive layers over a lower structure, the mold stack including a first horizontal conductive line, a second horizontal conductive line, and a pad between the first horizontal conductive line and the second horizontal conductive line;
forming a vertical stack of a stair structure whose height is gradually decreased in a stack direction that the conductive layers are stacked by selectively etching a portion of the mold stack;
forming contact holes in the stair structure, wherein heights of the contact holes are gradually decreased in the stack direction; and
forming contact plugs in the contact holes, the contact plugs coupled to the conductive layers, respectively.

2. The method of claim 1, wherein the first horizontal conductive line, the second horizontal conductive line, and the pad are formed to have the same horizontal length in the mold stack.

3. The method of claim 1, wherein the first horizontal conductive line, the second horizontal conductive line, and the pad are formed to have different horizontal lengths in the vertical stack.

4. The method of claim 1, wherein forming the vertical stack of the stair structure includes
etching the mold stack into a stair structure through a plurality of masking processes and a plurality of etching processes.

5. A method for fabricating a semiconductor device, the method comprising:
forming a first stack of first conductive layers over a lower structure, each first conductive layer including a pair of an upper horizontal conductive line and a lower horizontal conductive line;
forming a second stack of second conductive layers extending from the first stack over the lower structure, each second conductive layer including a first horizontal conductive line, a second horizontal conductive line, and a pad between the first horizontal conductive line and the second horizontal conductive line;
forming a vertical stack of a stair structure by selectively etching a portion of the second stack, the vertical stack including a plurality of levels whose heights are gradually decreased in a stack direction that the second conductive layers are stacked;
forming contact holes in the stair structure, wherein heights of the contact holes are gradually decreased in the stack direction; and
forming contact plugs in the contact holes, the contact plugs coupled to the second conductive layers, respectively.

6. The method of claim 5, wherein the first horizontal conductive line extends from the upper horizontal conductive line, and
the second horizontal conductive line extends from the lower horizontal conductive line.

7. The method of claim 5, wherein the first stack further includes
a horizontal layer disposed between the upper horizontal conductive line and the lower horizontal conductive line.

8. The method of claim 5, wherein the first horizontal conductive line, the second horizontal conductive line, and the pad are formed to have the same horizontal length in the second stack.

9. The method of claim 5, wherein horizontal lengths of the first horizontal conductive line, the second horizontal conductive line, and the pad are different for each level in the vertical stack.

10. The method of claim 5, wherein the first horizontal conductive line, the second horizontal conductive line, and the pad include the same material.

11. The method of claim 5, wherein the first horizontal conductive line, the second horizontal conductive line, and the pad include a metal-based material.

12. The method of claim 5, further comprising:
after forming the vertical stack of the stair structure,
forming a pad passivation layer that covers the stair structure.

13. A semiconductor device comprising:
a lower structure;
a first region formed over the lower structure, the first region including a plurality of first conductive layers that are vertically stacked in a first direction;
a second region including a plurality of second conductive layers stacked in the first direction and having different horizontal lengths, the second region extend from the first region; and
a plurality of contact structures respectively coupled to the second conductive layers,
wherein each of the second conductive layers includes:
a first horizontal conductive line;
a second horizontal conductive line; and
a pad between the first horizontal conductive line and the second horizontal conductive line.

14. The semiconductor device of claim 13, wherein the horizontal lengths of the first horizontal conductive line, the second horizontal conductive line, and the pad are different from each other.

15. The semiconductor device of claim 13, wherein each of the first conductive layers includes:
an upper horizontal conductive line extending from the first horizontal conductive line; and
a lower horizontal conductive line extending from the second horizontal conductive line.

16. The semiconductor device of claim 13, wherein each of the first conductive layers includes:
an upper horizontal conductive line extending from the first horizontal conductive line;
a lower horizontal conductive line extending from the second horizontal conductive line; and
a horizontal layer between the first horizontal conductive line and the second horizontal conductive line.

17. The semiconductor device of claim 13, wherein each of the contact structures includes:
a plurality of contact plugs respectively coupled to the second conductive layers.

18. The semiconductor device of claim 13, wherein each of the contact structures includes:
a plurality of contact plugs respectively coupled to the second conductive layers,
wherein the contact plugs have a structure in which heights of the contact plugs are gradually decreased in the first direction that the second conductive layers are stacked.

19. The semiconductor device of claim 13, wherein ends of the second conductive layers form a stair structure in the second region.

20. The semiconductor device of claim 13, wherein the first conductive layers and the second conductive layers include the same material.
